(19) United States
(12) Patent Application Publication
(10) Pub. No.: US 2026/0215328 A1
(43) Pub. Date: Jul. 23, 2026

(54) SEMICONDUCTOR DEVICE

(71) Applicant: RENESAS ELECTRONICS CORPORATION, Tokyo (JP)

(72) Inventors: Takayuki IGARASHI, Tokyo (JP); Tatsuo KASAOKA, Tokyo (JP); Taishu OYAMA, Tokyo (JP)

(21) Appl. No.: 19/422,790

(22) Filed: Dec. 17, 2025

(30) Foreign Application Priority Data
Jan. 23, 2025 (JP) 2025-010137

(51) Int. Cl. H10W 74/10; H10W 20/41; H10W 20/42; H10W 20/43; H10W 74/47; H10W 76/63; H10W 20/00; H10W 74/01

(52) U.S. Cl. CPC H10W 74/147; H10W 20/42; H10W 20/43; H10W 20/435; H10W 74/47; H10W 76/63; H10W 20/056; H10W 20/081; H10W 74/01

(57) ABSTRACT

A semiconductor device including: a semiconductor substrate including a chip region; and an interlayer insulating film on the semiconductor substrate is used, the chip region having: a circuit region; and a seal ring region positioned around the circuit region. The semiconductor device includes: a first wiring formed on the interlayer insulating film in the circuit region; and a second wiring formed on the interlayer insulating film in the seal ring region. The semiconductor device further includes: an insulating film covering the first wiring and the second wiring; and an organic insulating film on the insulating film IFT. A concave portion is formed on the upper surface of the second wiring. An end portion of the organic insulating film is positioned on a first portion, which is positioned closer to an edge portion of the chip region than the concave portion, of the second wiring.

### CROSS-REFERENCE TO RELATED APPLICATION

The disclosure of Japanese Patent Application No. 2025-010137 filed on January 23, 2025, including the specification, drawings and abstract is incorporated herein by reference in its entirety.

### BACKGROUND

The present invention relates to a semiconductor device, and particularly to a technique effectively applied to a semiconductor device in which the uppermost wiring configuring a multilayer wiring is covered with an organic insulating film.

A seal ring made of a metal member is known as a structure formed on an outer periphery of a semiconductor chip. The seal ring plays a role of preventing advancement of cracks in or water infiltration into a circuit region of the semiconductor chip due to a dicing step performed to obtain a plurality of semiconductor chips by cutting a semiconductor wafer. Additionally, the seal ring plays a role of preventing metallic contamination of the circuit region due to the dicing step.

There is disclosed technique listed below.

[Patent Document 1] Japanese Unexamined Patent Application Publication No. 2019-114673

The Patent Document 1 describes a configuration in which a polyimide film formed on the uppermost wiring of a plurality of stacked wirings is terminated immediately on a wiring configuring a seal ring.

### SUMMARY

If a horizontally-directional vicinity of an end portion of an organic insulating film for protecting the uppermost wiring of the multilayer wiring has a portion where a liquid developer for patterning the organic insulating film easily stays, the organic insulating film is easily peeled off by the stayed liquid developer. This causes voids in mold resin when the semiconductor device is sealed by the mold resin, and leads to a decrease in reliability of the semiconductor device.

Other object and novel characteristics will become apparent from the description of the present specification and the accompanying drawings.

An outline of a typical embodiment of the embodiments disclosed in the present application will be briefly described below.

A semiconductor device according to one embodiment includes: a semiconductor substrate including a chip region having a circuit region and a seal ring region positioned around the circuit region; and a first interlayer insulating film formed on the semiconductor substrate. The semiconductor device includes: a first wiring formed on the first interlayer insulating film in the circuit region; and a second wiring formed on the first interlayer insulating film in the seal ring region. The semiconductor device further includes: an inorganic insulating film covering the first wiring and the second wiring; and an organic insulating film formed on the inorganic insulating film. A concave portion is formed on an upper surface of the second wiring, and an end portion of the organic insulating film is positioned on a portion of the second wiring, the portion being positioned closer to the edge portion of the chip region than the concave portion.

According to one embodiment disclosed in the present application, reliability of a semiconductor device can be improved.

### BRIEF DESCRIPTIONS OF THE DRAWINGS

FIG. 1 is a plan view illustrating a semiconductor device according to a first embodiment.

FIG. 2 is a plan view illustrating the semiconductor device according to the first embodiment.

FIG. 3 is a cross-sectional view illustrating the semiconductor device taken along the line A-A of FIG. 2.

FIG. 4 is a cross-sectional view illustrating a partially-enlarged portion of FIG. 3.

FIG. 5 is a plan view illustrating the semiconductor device according to the first embodiment.

FIG. 6 is a cross-sectional view illustrating the semiconductor device according to the first embodiment.

FIG. 7 is a plan view illustrating the semiconductor device according to the first embodiment.

FIG. 8 is a schematic cross-sectional view taken along the line B-B of FIG. 7.

FIG. 9 is a cross-sectional view illustrating a steps of manufacturing the semiconductor device according to the first embodiment.

FIG. 10 is a cross-sectional view illustrating a steps of manufacturing the semiconductor device continued from FIG. 9.

FIG. 11 is a cross-sectional view illustrating a steps of manufacturing the semiconductor device continued from FIG. 10.

FIG. 12 is a cross-sectional view illustrating a steps of manufacturing the semiconductor device continued from FIG. 11.

FIG. 13 is a cross-sectional view illustrating a steps of manufacturing the semiconductor device continued from FIG. 12.

FIG. 14 is a cross-sectional view illustrating a steps of manufacturing the semiconductor device continued from FIG. 13.

FIG. 15 is a plan view illustrating a semiconductor device according to a second embodiment.

FIG. 16 is a cross-sectional view illustrating the semiconductor device taken along the line C-C of FIG. 15.

FIG. 17 is a schematic cross-sectional view illustrating the semiconductor device according to the second embodiment.

FIG. 18 is a cross-sectional view illustrating a steps of manufacturing the semiconductor device according to the second embodiment.

FIG. 19 is a cross-sectional view illustrating a steps of manufacturing the semiconductor device continued from FIG. 18.

FIG. 20 is a cross-sectional view illustrating a steps of manufacturing the semiconductor device continued from FIG. 19.

FIG. 21 is a cross-sectional view illustrating a steps of manufacturing the semiconductor device continued from FIG. 20.

FIG. 22 is a cross-sectional view illustrating a steps of manufacturing the semiconductor device continued from FIG. 21.

FIG. 23 is a cross-sectional view illustrating a steps of manufacturing the semiconductor device continued from FIG. 22.

FIG. 24 is a cross-sectional view illustrating a semiconductor device according to a first comparative example.

FIG. 25 is a plan view illustrating the semiconductor device according to the first comparative example.

FIG. 26 is a cross-sectional view illustrating the semiconductor device taken along the line D-D of FIG. 25.

FIG. 27 is a cross-sectional view illustrating a steps of manufacturing the semiconductor device according to the first comparative example.

FIG. 28 is a cross-sectional view illustrating a steps of manufacturing the semiconductor device continued from FIG. 27.

FIG. 29 is a cross-sectional view illustrating a steps of manufacturing the semiconductor device continued from FIG. 28.

FIG. 30 is a cross-sectional view illustrating a steps of manufacturing the semiconductor device continued from FIG. 29.

FIG. 31 is a cross-sectional view illustrating the semiconductor device according to the first comparative example.

FIG. 32 is a plan view illustrating a semiconductor device according to a second comparative example.

FIG. 33 is a cross-sectional view illustrating the semiconductor device according to the second comparative example.

FIG. 34 is a cross-sectional view illustrating a semiconductor device according to a third comparative example.

FIG. 35 is a plan view illustrating a semiconductor device according to a fourth comparative example.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted with the same reference symbols throughout all the drawings for describing the embodiments, and the repetitive description thereof will be omitted. In addition, in the following embodiments, the description of the same or similar portions is not repeated in principle unless otherwise particularly required.

### FIRST EMBODIMENT

### Details of Room for Improvement

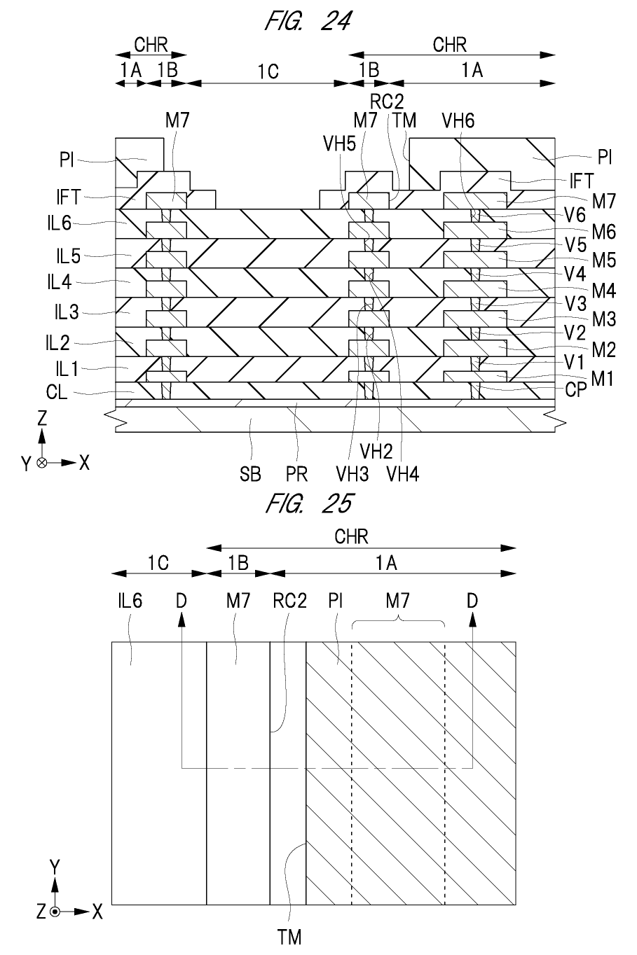

As described in the chapter “SUMMARY”, a horizontally-directional vicinity of an end portion of an organic insulating film for protecting the uppermost wiring of the multilayer wiring has a portion where a liquid developer for patterning the organic insulating film easily stays. In this case, the organic insulating film easily peels off. This leads to a decrease in reliability of the semiconductor device. Thus, the semiconductor device in which the multilayer wiring is protected by the organic insulating film has a room for improvement in preventing the peeling off of the end portion of the organic insulating film. Details of the room for improvement will be described below with reference to FIGS. 24 to 33.

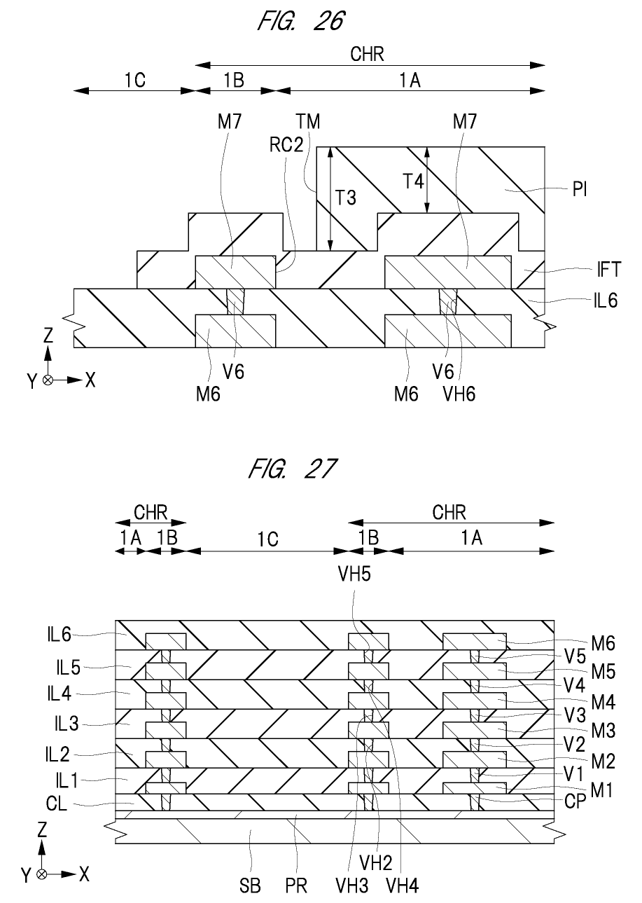

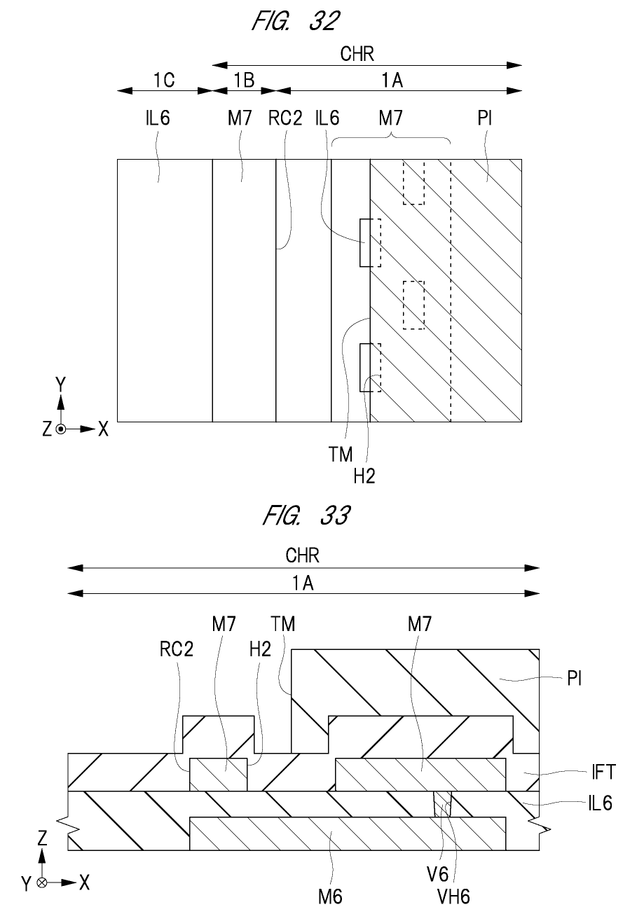

FIG. 24 is a cross-sectional view illustrating a semiconductor device according to a first comparative example. FIG. 25 is a plan view illustrating the semiconductor device according to the first comparative example. FIG. 26 is a cross-sectional view illustrating the semiconductor device taken along the line D-D of FIG. 25. FIGS. 27 to 30 are cross-sectional views illustrating the steps of manufacturing the semiconductor device according to the first comparative example. FIG. 31 is a cross-sectional view illustrating the semiconductor device according to the first comparative example. FIG. 32 is a plan view illustrating a semiconductor device according to a second comparative example. FIG. 33 is a cross-sectional view illustrating the semiconductor device according to the second comparative example.

The semiconductor device according to the first comparative example in which the multilayer wiring is provided on the semiconductor substrate. will be described here. A direction along an upper surface of the semiconductor substrate may be referred to as horizontal direction below. As illustrated in FIG. 24, a semiconductor substrate SB includes a plurality of chip regions CHR, and a scribe region 1C between the adjacent chip regions CHR. The chip region CHR includes a circuit region 1A positioned at the center of the chip region CHR and a seal ring region 1B on the periphery of the chip region CHR in plan view. The semiconductor substrate SB configures a semiconductor wafer obtained before cutting the scribe region 1C.

The semiconductor substrate SB has an upper surface and a lower surface opposite to the upper surface. The multilayer wiring is formed on the upper surface of the semiconductor substrate SB. The multilayer wiring includes a plurality of interlayer insulating films sequentially stacked on the semiconductor substrate SB, and a plurality of wirings formed as high as the interlayer insulating films. The multilayer wiring further includes a wiring M7 formed on the uppermost interlayer insulating film IL6 among the stacked interlayer insulating films. A “Z” direction is perpendicular to the upper surface of the semiconductor substrate SB. The wirings mutually overlapping in the Z direction are electrically connected to each other through a via. The uppermost interlayer insulating film IL6 among the interlayer insulating films covers a wiring M6. The interlayer insulating film IL6 on the wiring M6 is provided with a via hole VH6 penetrating the interlayer insulating film IL6. A via (via wiring) V6 as a conductive connector is embedded in the via hole VH6. A plurality of the uppermost wirings M7 in the multilayer wiring are formed on the interlayer insulating film IL6 and the via V6.

The wiring M7 is formed in each of the circuit region 1A and in the seal ring region 1B. The wiring M7 in the seal ring region 1B configures a seal ring. The upper surfaces and the side surfaces of the wirings M7 are covered with an insulating film IFT formed on the interlayer insulating film IL6 and the wirings M7. The insulating film IFT is, for example, a silicon nitride film. The insulating film IFT is not formed on a portion of the scribe region 1C.

As illustrated in FIG. 25, each of the wiring M7 in the seal ring region 1B and the wiring M7 formed in the chip region CHR and adjacent to the seal ring region 1B extends along the edge portion (periphery) of the chip region CHR. The adjacent wirings M7 are patterns formed on the interlayer insulating film IL6. Thus, as illustrated in FIG. 26, a concave portion (trench) RC2 is present between the adjacent wirings M7. That is, there is a region without a wiring between the two wirings M7. The concave portion RC2 has a side surface serving as the side surface of the wiring M7, and a bottom surface serving as the upper surface of the interlayer insulating film IL6.

An organic insulating film PI is formed on the insulating film IFT in the chip region CHR. The organic insulating film PI covers the wiring M7 in the circuit region 1A, and exposes the wiring M7 in the seal ring region 1B. The organic insulating film PI is made of, for example, polyimide. In FIG. 25, a contour of the wiring M7 covered with the organic insulating film PI is illustrated with a dashed line. The insulating film IFT is not illustrated in FIG. 25. A horizontally-directional end portion TM of the organic insulating film PI is positioned between the wiring M7 in the seal ring region 1B and the wiring M7 formed in the chip region CHR and adjacent to the seal ring region 1B in plan view. That is, the end portion TM overlaps the concave portion RC2 in plan view. The wiring M7 formed in the chip region CHR and adjacent to the seal ring region 1B is the outermost wiring M7 in the chip region CHR in plan view.

Next, a method of manufacturing the semiconductor device according to the first comparative example will be describe. First, as illustrated in FIG. 27, a semiconductor element (not illustrated) is formed in vicinity of the upper surface of the semiconductor substrate SB in the circuit region 1A. Next, an interlayer insulating film CL and a contact plug CP as a conductive connector penetrating the interlayer insulating film CL are formed on the semiconductor substrate SB. Next, a wiring layer, which includes a wiring M1, an interlayer insulating film IL1, and a via (via wiring) V1 penetrating the interlayer insulating film IL1 on the wiring M1, is formed on the interlayer insulating film CL and the contact plug CP. Next, a plurality of wiring layers are sequentially formed on the interlayer insulating film IL1 and the vias V1. Thereby, the structure of FIG. 27 is obtained. The uppermost interlayer insulating film IL6 covers the wiring M6 among the wiring layers.

Next, as illustrated in FIG. 28, the via hole VH6, which penetrates the interlayer insulating film IL6 and exposes the upper surface of the wiring M6, is formed. Next, a metal film is formed in the via hole VH6 and on the interlayer insulating film IL6, thereby filling the via hole VH6 with the metal film. The metal film is mainly made of, for example, tungsten (W). Next, the metal film on the interlayer insulating film IL6 is removed. Thereby, the via V6, which is made of the metal film remaining in the via hole VH6, is formed.

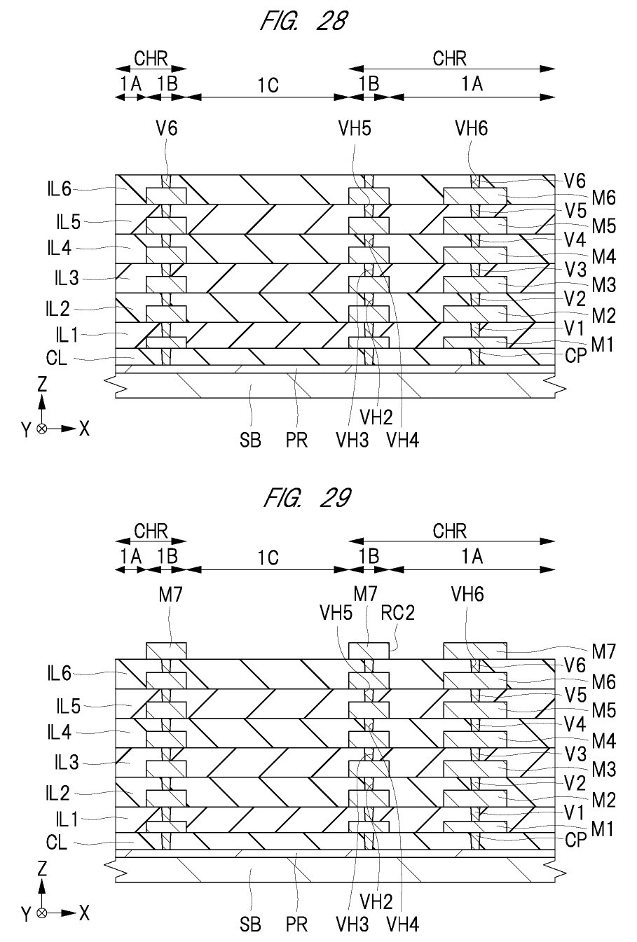

Next, as illustrated in FIG. 29, a metal film is formed on the interlayer insulating film IL6 and the via V6 penetrating the interlayer insulating film IL6. Next, the metal film on the interlayer insulating film IL6 is patterned, thereby forming the plurality of wirings M7 as metal patterns.

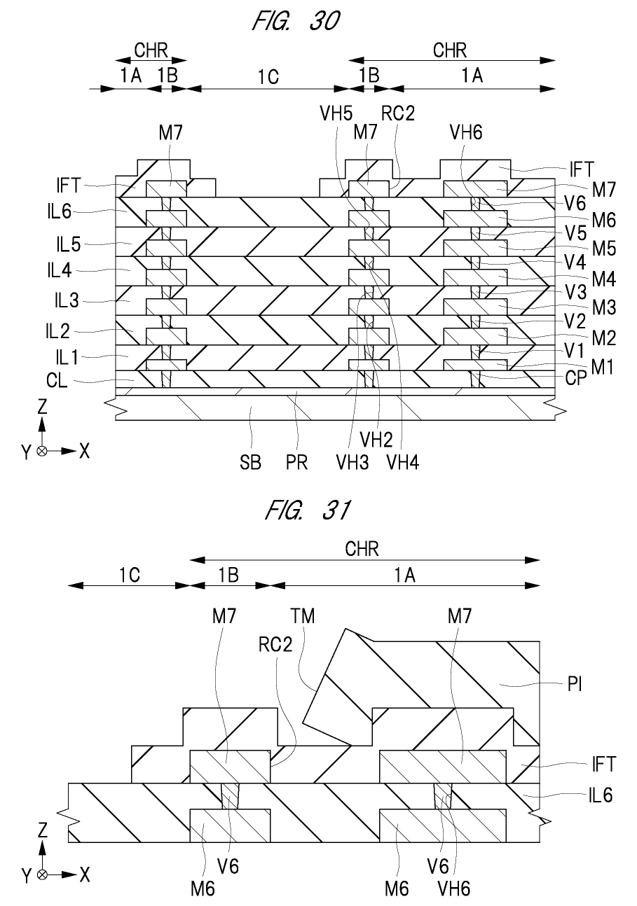

Next, as illustrated in FIG. 30, the insulating film IFT made of, for example, silicon nitride is formed on the interlayer insulating film IL6 and the wiring M7. Next, the insulating film IFT is patterned, thereby removing the insulating film IFT in the scribe region 1C. Next, the organic insulating film PI made of, for example, photosensitive polyimide is applied on the interlayer insulating film IL6 and the insulating film IFT. The photosensitive polyimide is a material which is solidified when being irradiated with light (such as ultraviolet light) and thus is resistant to the liquid developer.

Next, as illustrated in FIG. 26, the organic insulating film PI is selectively exposed to light. That is, the organic insulating film PI is irradiated with ultraviolet light under use of a photomask by which a portion to be finally left in the organic insulating film PI is irradiated with light. Next, a portion having been not irradiated with the ultraviolet light in the organic insulating film PI is removed by the liquid developer. That is, a step of patterning the organic insulating film PI and being called development is performed. Thereby, the organic insulating films PI in the seal ring region 1B and the scribe region 1C are removed. The semiconductor device according to the first comparative example illustrated in FIGS. 24, 25, and 26 is completed through the above steps.

The semiconductor substrate SB is thermally processed in the step of forming the organic insulating film PI. The semiconductor substrate SB including the organic insulating film PI is thermally processed also after the organic insulating film PI is developed. The thermal processings are referred to as, for example, curing or baking. The curing is a thermal processing for heating and hardening thermosetting resin. The baking is a thermal processing of performing a heating process to vaporize the absorbed moisture, thereby preventing crack or deformation of the resin caused by the moisture. The organic insulating film PI is shrunk by the thermal processings. For example, if a thickness of the organic insulating film PI immediately after the application is about 11 μm, a thickness of the thermally-processed organic insulating film PI is about 5 μm.

FIG. 31 illustrates the end portion TM of the organic insulating film PI deformed and peeled off from the insulating film IFT. As described above, the liquid developer is used in the step of patterning the organic insulating film PI. Even in the portion irradiated with ultraviolet light in the light exposure step in the organic insulating film PI, the liquid developer may infiltrate into a gap between the organic insulating film PI and the insulating film IFT immediately below the organic insulating film PI if the end portion TM is in contact with the liquid developer for a long time. In this case, the end portion of the organic insulating film PI easily peels off from the insulating film IFT. In FIG. 31, the end portion TM of the organic insulating film PI is positioned between the adjacent wiring M7, in other words, positioned in the concave portion RC2. In this case, the liquid developer easily stays between the side surface of the wiring M7 formed in the seal ring region 1B and the side surface (edge surface) of the end portion TM of the organic insulating film PI which faces this side surface. Thus, there is a risk of the remaining of the liquid developer in the concave portion RC2 even after the step of patterning the organic insulating film PI. In this case, the liquid developer staying in the concave portion RC2 infiltrates into a gap between the organic insulating film PI and the insulating film IFT immediately below the organic insulating film PI, and thus, the end portion of the organic insulating film PI easily peels off from the insulating film IFT.

As described above, the organic insulating film PI is shrunk by the thermal processings performed in the steps of manufacturing the semiconductor device. In this case, the organic insulating film PI is thicker than the interlayer insulating film IL6. The organic insulating film PI has a thickness of, for example, 5 μm. The interlayer insulating film IL6 has a thickness of, for example, 2 μm. As illustrated in FIG. 26, the thickness T3 of the organic insulating film PI, which overlaps the concave portion RC2 formed between the wiring M7 provided in the circuit region 1A and the wiring M7 provided in the seal ring region 1B in plan view, is larger than the thickness T4 of the organic insulating film PI positioned on the wiring M7. A thicker portion of the organic insulating film PI has higher stress caused by heating, and thus, is easier to be shrunk. Thus, when the end portion TM of the organic insulating film PI overlaps the concave portion RC2 in plan view, the organic insulting film PI easily deforms in vicinity of the end portion TM of the organic insulating film PI. Consequently, the end portion of the organic insulating film PI easily peels off from the insulating film IFT.

As described above, when the end portion TM of the organic insulating film PI overlaps the concave portion RC2 in plan view, the organic insulating film PI in vicinity of the end portion TM easily peels off from the insulating film IFT. That is, the organic insulating film PI easily peels off from the insulating film IFT since the liquid developer easily stays in the concave portion RC2 where the end portion TM of the organic insulating film PI is positioned, and since the organic insulating film PI is thick at the edge portion. In other words, the adhesion of the organic insulating film PI to the insulating film IFT decreases. As illustrated in FIG. 31, the peeling off of the end portion of the organic insulating film PI from the insulating film IFT causes a gap between the end portion of the organic insulating film PI and the insulating film IFT. The gap is not sealed and is left as a void in some cases when the semiconductor device is sealed by the mold resin after the steps of manufacturing the semiconductor device described in FIGS. 26 to 30. The insulating performance of the semiconductor device is made lower in a case with the existence of the void than a case without the void between the end portion of the organic insulating film PI and the insulating film IFT. That is, the reliability of the semiconductor device decreases.

Such a problem arises also when the end portion TM of the organic insulating film PI is positioned in the hole penetrating the wiring M7 in the Z direction. FIGS. 32 and 33 illustrate a configuration of a semiconductor device according to a second comparative example. The configuration of the semiconductor device according to the second comparative example is the same as the configuration of the semiconductor device according to the first comparative example, except for the position of the end portion TM of the organic insulating film PI and the shape of some wirings M7.

The wiring M7 has a thickness of, for example, 1.6 μm, and are the wiring patterns thicker than, for example, the wiring M1. In plan view, the width (which is the length in the X direction in FIG. 33) of the wiring M7 adjacent to the seal ring region 1B is larger than the width (which is the length in the X direction in FIG. 33) of the wiring M7 configuring the seal ring. In this way, the wiring M7 with a larger volume remarkably shrinks when heated. The insulating film IFT covering the wiring M7 is made of silicon nitride (SiN) which is harder than the metal (such as aluminum (Al)) configuring the wiring M7. Thus, when the wider wiring M7 shrinks at high temperature, the insulating film IFT can crack. Thus, the wiring M7 on the outer periphery of the chip region CHR is provided with a plurality of holes H2 which are called slits. The holes H2 are provided in a staggered pattern in plan view. Since the holes H2 are provided, the insulating film IFT is difficult to crack at high temperature. The holes H2 penetrate from the upper surface of the wiring M7 to the lower surface thereof.

One portion of the end portion TM of the organic insulating film PI overlaps the wiring M7 on the outer periphery of the chip region CHR in plan view. The other portion of the end portion TM of the organic insulating film PI overlaps the holes H2 provided in the wiring M7 on the outer periphery of the chip region CHR in plan view. In this case, the holes H2 are portions in which the liquid developer used in the step of patterning the organic insulating film PI easily stays, as well as portions with the maximized thickness of the organic insulating film PI. Thus, the organic insulating film PI in and in vicinity of the holes H2 easily peels off from the insulating film IFT.

The problem of the easy peeling off of the end portion of the organic insulating film PI similarly arises when the insulating film IFT is an inorganic insulating film, whether or not the insulating film IFT in contact with the lower surface and a portion of the side surface of the organic insulating film PI is a silicon nitride film. For example, the problem of the easy peeling off of the end portion of the organic insulating film PI also arises when the insulating film IFT is a silicon oxide film.

From the above, the semiconductor device in which the wiring, the interlayer insulating film and the like are protected by the organic insulating film PI has the room for improvement in preventing the peeling off of the end portion of the organic insulating film PI from the insulating film IFT.

Accordingly, in the first embodiment, a devisal is made for overcoming the room for improvement. A technical concept of the first embodiment with the devisal will be described below.

### Configuration of Semiconductor Device

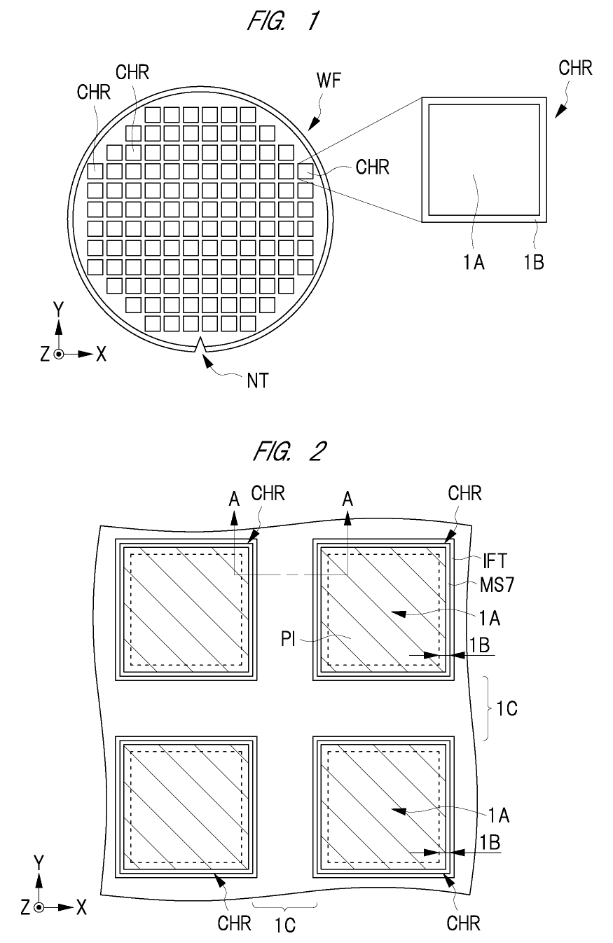

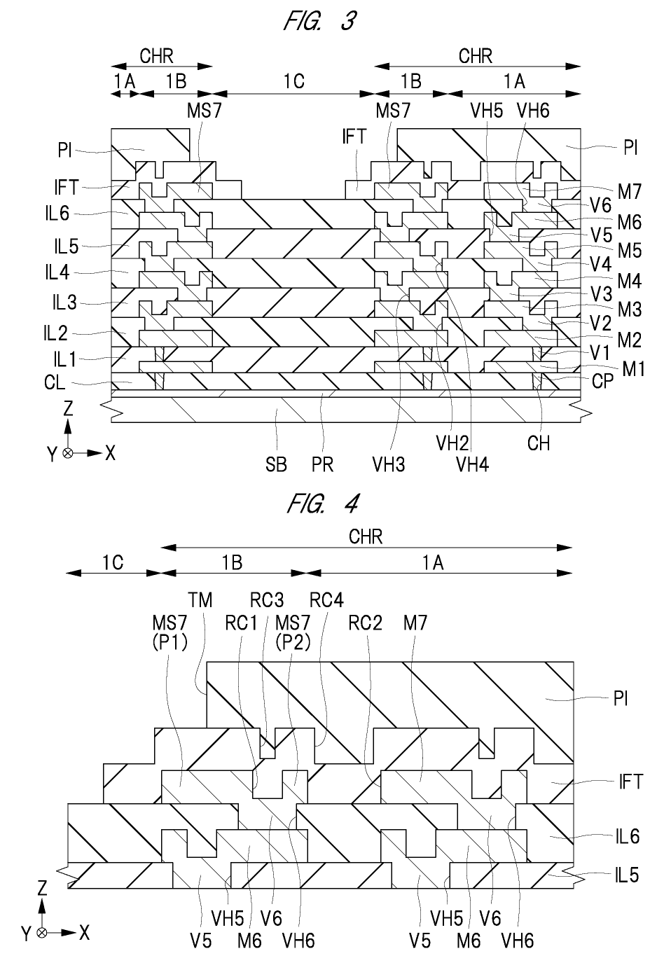

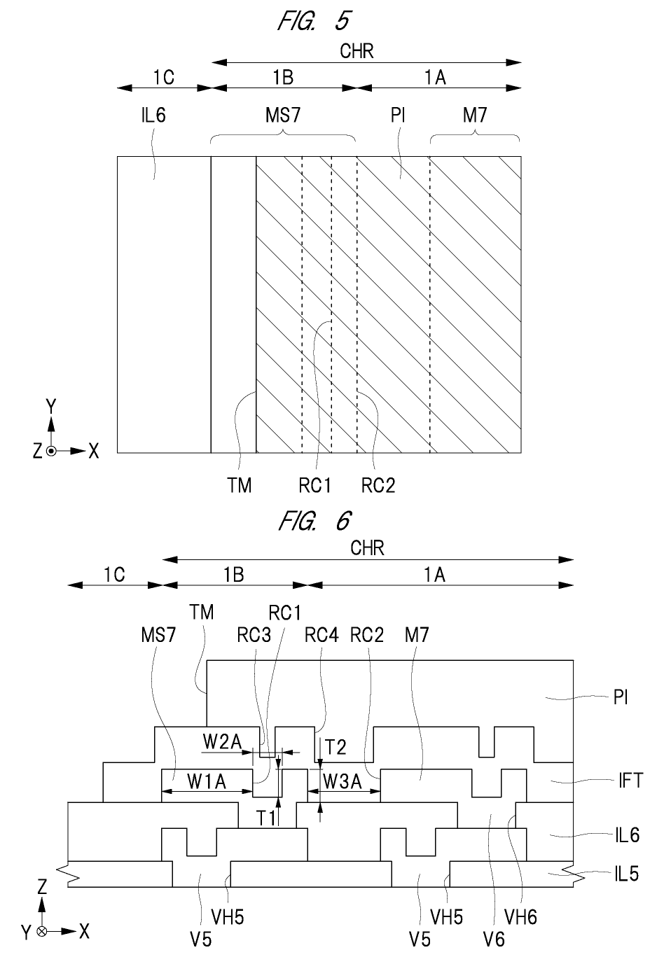

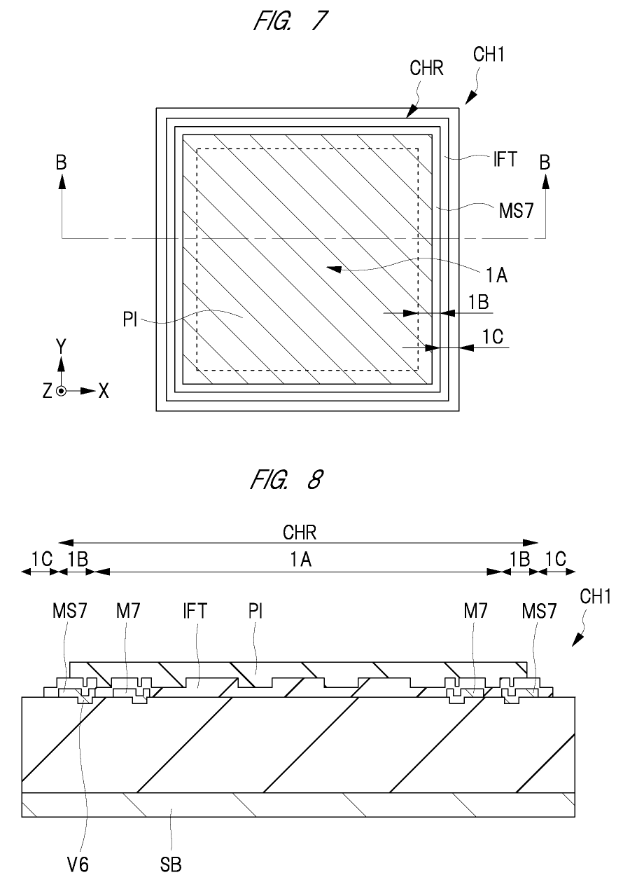

A configuration of the semiconductor device according to the first embodiment will be described below with reference to FIGS. 1 to 6. FIG. 1 is a plan view illustrating the semiconductor device according to the first embodiment. FIG. 2 is a plan view illustrating the semiconductor device according to the first embodiment. FIG. 3 is a cross-sectional view illustrating the semiconductor device taken along the line A-A of FIG. 2. FIG. 4 is a cross-sectional view illustrating a partially-enlarged portion of of FIG. 3. FIG. 5 is a plan view illustrating the semiconductor device according to the first embodiment. FIG. 6 is a cross-sectional view illustrating the semiconductor device according to the first embodiment. In each plan view except for FIG. 1, the organic insulating film PI is hatched to make the drawing simple.

FIG. 1 illustrates a plan view of the semiconductor wafer WF including the semiconductor device according to the first embodiment and an enlarged plan view in which one of the plurality of chip regions CHR arranged in the matrix pattern on the upper surface of the semiconductor wafer WF is picked up.

The semiconductor wafer WF, that is, the semiconductor substrate SB is circular in plan view. One/some edge portions of the semiconductor wafer WF has a notch NT in plan view. The chip regions CHR are arranged in the matrix pattern on the upper surface of the semiconductor wafer WF. Each chip region CHR is rectangular, and includes the rectangular circuit region 1A and a seal ring region 1B surrounding the circuit region 1A in plan view. The seal ring region 1B extends along the four sides of the chip region CHR in plan view. The circuit region 1A is, for example, a region where an analog circuit is formed. The circuit region 1A is a region where an element, a wiring and the like configuring the circuit are formed.

The seal ring region 1B is a region where a seal ring is arranged. The seal ring prevents cracking inside the seal ring region 1B when the semiconductor wafer WF is cut by a dicer (dicing blade). Further, the seal ring prevents the water infiltration into the circuit region 1A and the metal contamination of the circuit region 1A when the semiconductor wafer WF is cut by the dicer. Thus, the seal ring is continuously formed along the seal ring region 1B to surround the circuit region 1A in plan view. The short-wise width of the seal ring region 1B, in other words, the length of the seal ring region in the direction crossing the extending direction of the seal ring region 1B is, for example, about 20 μm.

The chip regions CHR are arranged in the X direction and in the Y direction along the upper surface of the semiconductor wafer WF. The X direction and the Y direction are perpendicular to each other in plan view. Each of the X direction and the Y direction is the direction along the upper surface of the semiconductor wafer WF. The X direction and the Y direction are perpendicular to the Z direction. The chip regions CHR on the upper surface of the semiconductor wafer WF separate from one another. A region between the adjacent chip regions CHR is a scribe region 1C. Each chip region CHR is surrounded by the scribe region 1C in plan view.

The scribe region 1C extends in the X direction and in the Y direction. The scribe region 1C extending in the X direction is perpendicular to the scribe region 1C extending in the Y direction. The short-wise width of the scribe region 1C extending in one direction is, for example, about 100 μm. The scribe region 1C is a region partially cut along the extending direction of the scribe region 1C. That is, the scribe region 1C is a partially-removed region for separating the chip regions CHR from one another. Each chip region CHR pieced by cutting is to be a semiconductor chip. That is, the chip region CHR is a region to be one semiconductor chip after the dicing step. FIG. 2 illustrates four chip regions CHR arranged on the upper surface of the semiconductor wafer WF of FIG. 1 in plan view while being enlarged. The center of the scribe region 1C in the short-wise direction is a region cut (removed) by dicing. A portion of the scribe region 1C not cut but left by the dicing step is left as the edge portion of the semiconductor chip.

FIG. 3 is a cross-sectional view illustrating the semiconductor device provided when the scribe region 1C is not cut. FIG. 3 is a cross-sectional view of the seal ring region 1B and the scribe region 1C in the short-wise direction. The seal ring region 1B is present between the scribe region 1C and the circuit region 1A.

As illustrated in FIG. 3, the semiconductor device includes the semiconductor substrate SB. The semiconductor substrate SB is a p-type semiconductor substrate made of single crystal silicon (Si). The semiconductor device has an upper surface on which an element is formed and a lower surface opposite to the upper surface. The semiconductor substrate SB has a stack configuration including a substrate and an epitaxial layer (semiconductor region) formed on the substrate by epitaxial growth. A p-type semiconductor region PR is formed in the semiconductor substrate SB from the upper surface of the semiconductor substrate SB down to a predetermined depth. The impurity concentration of the semiconductor region PR is higher than the impurity concentration of the semiconductor substrate SB below the semiconductor region PR.

An interlayer insulating film CL is formed on the semiconductor substrate SB. The interlayer insulating film CL is mainly made of, for example, a silicon nitride film or a silicon oxide film, and an upper surface of the interlayer insulating film CL is flattened. The interlayer insulating film CL is mainly made of, for example, a tetraethyl orthosilicate (TEOS) film. A plurality of contact holes (connection holes) CH, which penetrate from the upper surface toward the lower surface of the interlayer insulating film CL, are formed in the circuit region 1A and the seal ring region 1B. The contact plugs (conductive connectors) CP are formed in the contact holes CH, respectively. The contact plug CP is made of a conductor embedded in the contact hole CH. The contact plug CP is mainly made of tungsten (W). Each of the contact plugs CP is electrically connected to, for example, the semiconductor region PR. The upper surface of the contact plug CP and the upper surface of the interlayer insulating film CL are flattened to be substantially the same surface.

A first wiring layer, which includes a plurality of wirings M1 and an interlayer insulating film IL1 covering the side surfaces and the upper surfaces of the wirings M1, is formed on the interlayer insulating film CL. The first wiring layer includes vias (via wirings) V1 penetrating the interlayer insulating film IL1 and connected to the upper surfaces of the wirings M1. The interlayer insulating film IL1 is mainly made of, for example, a silicon oxide film, the wiring M1 is mainly made of, for example, aluminum (Al), and the via V1 is mainly made of, for example, tungsten (W). A portion of the lower surface of the wiring M1 is connected to the upper surface of the contact plug CP. The horizontal width of the wiring M1 is larger than the horizontal width of each of the contact plug CP and the via V1. The upper surface of each via V1 and the upper surface of the interlayer insulating film IL1 are flattened to be substantially the same surface.

A second wiring layer is formed on the first wiring layer. The second wiring layer is made of a plurality of wirings M2 formed on the interlayer insulating film IL1 and the via V1, an interlayer insulating film IL2 covering the wirings M2, and vias (via wirings) V2 formed on the wirings M2. The via V2 penetrates the interlayer insulating film IL2, and is connected to the upper surface of the wiring M2. The via V2 is a portion of a wiring M3 formed in a via hole (connection hole) VH2 penetrating the interlayer insulating film IL2. The interlayer insulating film IL2 is mainly made of, for example, a silicon oxide film. Each of the wiring M2 and the via V2 is mainly made of, for example, aluminum (Al). A portion of the lower surface of the wiring M2 is connected to the upper surface of the via V1. The width of the wiring M2 in the horizontal direction is larger than the width of each of the via V1 and the via V2 in the horizontal direction.

A third wiring layer, a fourth wiring layer, a fifth wiring layer, and a sixth wiring layer, each having the same configuration as that of the second wiring layer, are sequentially stacked on the second wiring layer. That is, the third wiring layer includes a plurality of wirings M3 connected to the vias V2, an interlayer insulating film IL3 covering the wirings M3, and vias (via wirings) V3 penetrating the interlayer insulating film IL3 and connected to the upper surfaces of the wirings M3. The wiring M3 is integrated with the via V2. That is, in the present embodiment, one portion (via V2) of the wiring M3 is positioned in the via hole VH2, and the other portion (other than the via V2) of the wiring M3 is positioned on the interlayer insulating film IL2. A concave portion is formed on the upper surface of the wiring M3 immediately on the via V2. The via V3 is a portion of a wiring M4 formed in the via hole VH3 penetrating the interlayer insulating film IL3.

The fourth wiring layer includes a plurality of wirings M4 connected to the vias V3, an interlayer insulating film IL4 covering the wirings M4, and a plurality of vias V4 penetrating the interlayer insulating film IL4 and connected to the upper surfaces of the wirings M4. The wiring M4 is integrated with the via V3. That is, in the present embodiment, one portion (via V3) of the wiring M4 is positioned in the via hole VH3, and the other portion (other than the via V3) of the wiring M4 is positioned on the interlayer insulating film IL3. A concave portion is formed on the upper surface of the wiring M4 immediately on the via V3. The via (via wiring) V4 is a portion of a wiring M5 formed in the via hole VH4 penetrating the interlayer insulating film IL4.

The fifth wiring layer includes a plurality of wirings M5 connected to the vias V4, an interlayer insulating film IL5 covering the wirings M5, and a plurality of vias (via wirings) V5 penetrating the interlayer insulating film IL5 and connected to the upper surfaces of the wirings M5. The wiring M5 is integrated with the via V4. That is, in the present embodiment, one portion (via V4) of the wiring M5 is positioned in the via hole VH4, and the other portion (other than the via V4) of the wiring M5 is positioned on the interlayer insulating film IL4. A concave portion is formed on the upper surface of the wiring M5 immediately on the via V4. The via V5 is a portion of the wiring M6 formed in the via hole VH5 penetrating the interlayer insulating film IL5.

The sixth wiring layer includes a plurality of wirings M6 connected to the vias V5, an interlayer insulating film IL6 covering the wirings M6, and a plurality of vias (via wirings) V6 penetrating the interlayer insulating film IL6 and connected to the upper surfaces of the wirings M6. The wiring M6 is integrated with the via V5. That is, in the present embodiment, one portion (via V5) of the wiring M6 is positioned in the via hole VH5, and the other portion (other than the via V5) of the wiring M6 is positioned on the interlayer insulating film IL5. A concave portion is formed on the upper surface of the wiring M6 immediately on the via V5. The interlayer insulating film IL6 is the uppermost interlayer insulating film. The via V6 is a portion of the wiring M6 formed in the via hole VH6 penetrating the interlayer insulating film IL6. The multilayer wiring is made of the contact plug CP, the vias V1 to V6 and the wirings M1 to M6. A plurality of such a multilayer wiring is formed in the circuit region 1A and also the seal ring region 1B. The multilayer wiring may be formed in the scribe region 1C. The vias V1 to V6 are conductive connectors.

A plurality of wirings M7 are formed on the interlayer insulating film IL6 in the circuit region 1A. The wiring M7 is connected to the via V6 immediately below the wiring M7. The wiring M7 is integrated with the via V6. That is, in the present embodiment, one portion (via V6) of the wiring M7 is positioned in the via hole VH6 provided in the circuit region 1A, and the other portion (other than the via V6) of the wiring M7 is positioned on the interlayer insulating film IL6. The wiring M7 is the uppermost wiring in the multilayer wiring. A wiring MS7 is formed on the interlayer insulating film IL6 in the seal ring region 1B. The wiring MS7 is connected to the via V6 immediately below the wiring MS7. The wiring MS7 is integrated with the via V6. That is, in the present embodiment, one portion (via V6) of the wiring MS7 is positioned in the via hole VH6 provided in the seal ring region 1B, and the other portion (other than the via V6) of the wiring MS7 is positioned on the interlayer insulating film IL6. The wiring MS7 is the uppermost wiring in the multilayer wiring formed in the seal ring region 1B.

The insulating film IFT is formed on the wiring M7, the wiring MS7, and the interlayer insulating film IL6. The insulating film IFT is, for example, a silicon nitride film. The upper surfaces and the side surfaces of the wirings M7 and MS7 are covered with the insulating film IFT. The upper surface of the insulating film IFT has surface irregularity to follow the underlying shape of the insulating film IFT, that is, the shapes of the upper surfaces and the side surfaces of the wirings M7 and MS7 and the upper surface of the interlayer insulating film IL6. The insulating film IFT is formed only on both edge portions of the scribe region 1C in the short-wise direction.

The organic insulating film PI is formed on the insulating film IFT. The organic insulating film PI is made of, for example, polyimide. The organic insulating film PI covers the wirings M7 in the circuit region 1A and partially covers the wiring MS7 in the seal ring region 1B. The upper surface of the organic insulating film PI is flat. Although not illustrated, the organic insulating film PI and the insulating film IFT include openings for exposing the upper surfaces of the wirings M7. The upper surfaces of the wirings M7 exposed at the bottoms of the openings configure, for example, electrode pads connected to boding wires.

The multilayer wiring is not formed in the scribe region 1C herein, but may be formed in the scribe region 1C.

The thickness of each of the interlayer insulating films IL2 to IL6 is, for example, 2.7 μm. The thickness of each of the wirings M2 to M7 and MS7 is, for example, 1.6 μm. The height of each of the vias V2 to V6 is, for example, 1.1 μm. The thickness of the insulating film IFT is, for example, 2.0 μm. The thickness of the organic insulating film PI is, for example, 5.0 μm.

And, for example, a coil (inductor, transformer) is formed in a region at the center of the circuit region 1A in plan view although not illustrated. The coil is made of, for example, a lower inductor formed as high as the wirings M2 and an upper inductor formed as high as the wirings M7.

The wirings M1 to M6, the wiring MS7, the vias V1 to V6, and the contact plug CP, which configure the multilayer wiring in the seal ring region 1B, are electrically connected to one another. The multilayer wiring formed in the seal ring region 1B configures a seal ring. The seal ring is electrically connected to the semiconductor substrate SB via the semiconductor region PR. The wirings M1 to M7, the vias V1 to V6, and the contact plugs CP, which configure the multilayer wiring in the circuit region 1A, are electrically connected to one another. The multilayer wiring formed in the circuit region 1A is electrically connected to the semiconductor substrate SB via the semiconductor region PR. The multilayer wiring formed in the circuit region 1A is electrically connected to the coil and configures a circuit therewith. That is, the wiring M7 is a wiring electrically connected to the element. To the contrary, the seal ring does not configure a circuit. That is, the wirings M1 to M6 and MS7, which configure the multilayer wiring in the seal ring region 1B, are virtual wirings.

As illustrated in FIG. 4, a concave portion (trench) RC1 is formed on the upper surface of the wiring MS7 immediately on the via V6. As illustrated in FIG. 4, the concave portion RC1 is arranged between one and the other edge portions of the wiring MS7 in its extending direction (the X direction in FIG. 4). As illustrated in FIG. 5, on the upper surface of the wiring MS7, the concave portion RC1 is formed in a slit pattern along the periphery of the chip region CHR. The insulating film IFT is not illustrated in FIG. 5. The contours (edge portions) of the wiring MS7 and the wiring M7 covered with the organic insulating film PI are illustrated with a dashed line in FIG. 5.

As illustrated in FIG. 4, a concave portion RC2 is present between the adjacent wirings MS7 and M7. The bottom surface of the concave portion RC1 is made of the upper surface of the wiring MS7 or the upper surface of the via V6. To the contrary, the bottom surface of the concave portion RC2 is made of the upper surface of the interlayer insulating film IL6. A concave portion RC3 is formed on the upper surface of the insulating film IFT covering the wiring MS7. The concave portion RC3 is positioned immediately on the concave portion RC1. A concave portion RC4 is formed on the upper surface of the insulating film IFT immediately on the region between the adjacent wirings MS7 and M7. The concave portion RC4 is positioned immediately on the concave portion RC2.

The organic insulating film PI is continuously formed from the center of the circuit region 1A to the immediately on portion of the wiring MS7. The end portion TM of the organic insulating film PI is positioned on the wiring MS7 which is positioned closer to the edge portion (periphery) of the chip region CHR than the concave portion RC1. The concave portions RC1 to RC4 are covered with the organic insulating film PI. In the wiring MS7 adjacent to the concave portion RC1, the width of the wiring MS7 (first portion P1) being positioned closer to the edge portion of the chip region CHR is larger than the width of the wiring MS7 (second portion P2) being positioned closer to the circuit region 1A in the short-wise direction (the X direction in FIG. 4) of the wiring MS7.

In other words, the wiring MS7 includes the first portion P1 being positioned closer to the edge portion of the chip region CHR than the concave portion RC1, and the second portion P2 farther away from the edge portion of the chip region CHR than the concave portion RC1. The length of the first portion P1 in a second direction crossing a first direction which is the extending direction of the wiring MS7 is larger than the length of the second portion P2 in the second direction in plan view. In the short-wise direction of the wiring MS7, the organic insulating film PI terminates immediately on the wider wiring MS7 (first portion P1) of the wiring MS7 adjacent to the concave portion RC1. In other words, in the short-wise direction of the wiring MS7, the end portion TM of the organic insulating film PI overlaps the wider wiring MS7 (first portion P1) of the wiring MS7 adjacent to the concave portion RC1 in plan view.

FIG. 6 illustrates a cross-sectional surface at the same position as that of FIG. 4. In FIG. 6, hatching is omitted. As illustrated in FIG. 6, in the short-wise direction of the wiring MS7, the width of the wiring MS7 is W1A, the width extending from the edge portion of the wiring MS7 being positioned closer to the edge portion of the chip region CHR to the concave portion RC1 which is the closest concave portion in the direction toward the circuit region 1A. In the short-wise direction of the wiring MS7, the width of the concave portion RC1 is W2A, the concave portion which is the closest in the direction toward the circuit region 1A from the edge portion of the wiring MS7 being positioned closer to the edge portion of the chip region CHR. In the short-wise direction of the wiring MS7, the distance between the adjacent wirings MS7 and M7 is W3A.

The thickness of the metal film embedded in the via hole VH6 is larger than the height of the via hole VH6. Thus, the bottom surface of the concave portion RC1 is positioned higher than the upper surface of the interlayer insulating film IL6 in the Z direction (height direction). Thus, the depth T1 of the concave portion RC1 is smaller than the depth T2 of the concave portion RC2. Thus, the depth of the concave portion RC3 is smaller than the depth of the concave portion RC4. The depth T1 of the concave portion RC1 is, for example, 1.2 μm. The depth T2 of the concave portion RC2 is, for example, 1.6 μm.

FIG. 7 is a plan view illustrating a semiconductor chip CH1 obtained from the semiconductor wafer WF by cutting the scribe region 1C. One semiconductor chip CH1 is made of one chip region CHR and a portion of the scribe region 1C therearound. The planar shape of the semiconductor substrate configuring the semiconductor chip CH1 is a quadrangular shape having a first side extending in the first direction (the X direction or the Y direction).

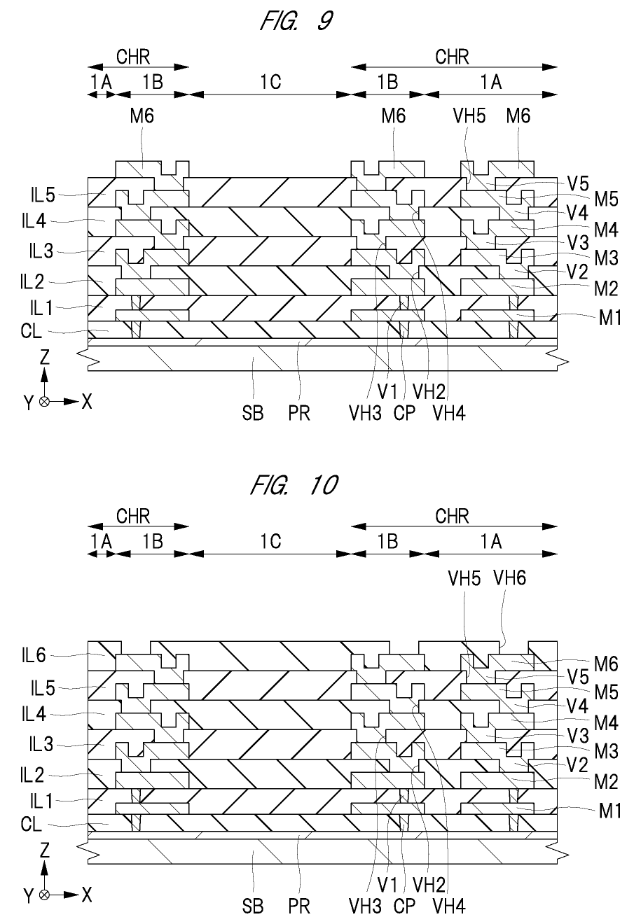

FIG. 8 is a schematic cross-sectional view taken along the line B-B of FIG. 7. FIG. 8 schematically illustrates a configuration of the semiconductor chip CH1, and particularly simply illustrates a configuration of the multilayer wiring and a configuration of the circuit region 1A. As illustrated in FIG. 8, the organic insulating film PI is formed from the circuit region 1A to the seal ring region 1B. In other words, the organic insulating film PI is formed from the seal ring region 1B on one edge portion of the semiconductor chip CH1 to the seal ring region 1B on its opposite edge portion thereof.

### Method of Manufacturing Semiconductor Device

A method of manufacturing the semiconductor device according to the first embodiment will be described below with reference to FIGS. 3 and 9 to 14. FIGS. 9 to 14 are cross-sectional views illustrating the steps of manufacturing the semiconductor device according to the first embodiment.

First, as illustrated in FIG. 9, the p-type semiconductor substrate SB is prepared. Next, p-type impurities are implanted into the upper surface of the semiconductor substrate SB by ion implantation. Thereby, the semiconductor region PR having the depth from the upper surface of the semiconductor substrate SB down to a predetermined depth is formed in the semiconductor substrate SB. Next, the interlayer insulating film CL and the plurality of contact plugs CP as conductive connectors penetrating the interlayer insulating film CL are formed on the semiconductor substrate SB in the seal ring region 1B and the circuit region 1A. Next, the first wiring layer, which includes the wirings M1, the interlayer insulating film IL1, and the vias V1 penetrating the interlayer insulating film IL1 on the wirings M1, is formed on the interlayer insulating film CL and the contact plugs CP.

Next, the second wiring layer, which includes the wirings M2, the interlayer insulating film IL2, and the vias V2 penetrating the interlayer insulating film IL2 on the wirings M2, is formed on the interlayer insulating film IL1 and the vias V1. In this case, the interlayer insulating film IL2 covering the interlayer insulating film IL1 and the wirings M2 is formed after the wirings M2 as wiring patterns are formed on the interlayer insulating film IL1 and the vias V1 in the seal ring region 1B and the circuit region 1A. Next, the upper surface of the interlayer insulating film IL2 is flattened by chemical mechanical polishing (CMP), and then, the via holes VH2 penetrating the interlayer insulating film IL2 immediately on the wirings M2 are formed. Next, a metal film is formed in the via holes VH2 and on the interlayer insulating film IL2 and is patterned, thereby forming the vias V2 made of the metal film in the via holes VH2. At this time, the metal film formed and patterned on the interlayer insulating film IL2 configures the wirings M3.

Next, the third wiring layer, the fourth wiring layer, and the fifth wiring layer are formed on the second wiring layer by the same steps as the steps of forming the second wiring layer. The third wiring layer includes the wirings M3, the interlayer insulating film IL3, and the vias V3 penetrating the interlayer insulating film IL3 on the wirings M3. The fourth wiring layer includes the wirings M4, the interlayer insulating film IL4, and the vias V4 penetrating the interlayer insulating film IL4 on the wirings M4. The fifth wiring layer includes the wirings M5, the interlayer insulating film IL5, and the vias V5 penetrating the interlayer insulating film IL5 on the wirings M5. The wirings M6 connected to the vias V5 are formed on the interlayer insulating film IL5 by the step of forming the vias V5.

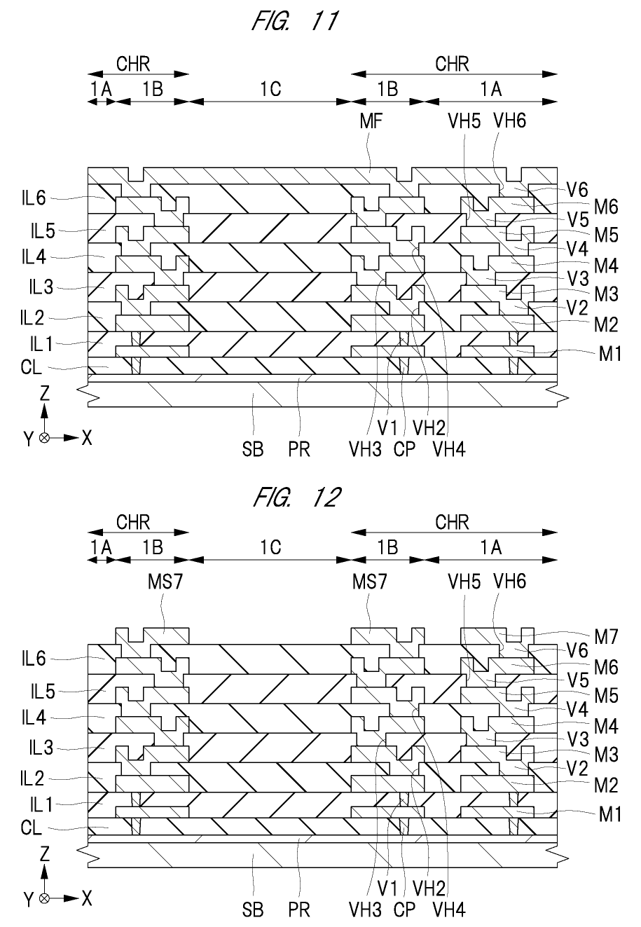

Next, the interlayer insulating film IL6 covering the interlayer insulating film IL5 and the wirings M6 is formed as illustrated in FIG. 10. The interlayer insulating film IL6 is made of, for example, a silicon oxide film. The interlayer insulating film IL6 can be formed by, for example, chemical vapor deposition (CVD). Next, the upper surface of the interlayer insulating film IL6 is flattened by, for example, CMP. Next, the via holes VH6, which penetrate the interlayer insulating film IL6 and expose the upper surfaces of the wirings M6, are formed by photolithography and dry etching. The height of the via hole VH6 is, for example, 1.1 μm.

Next, the metal film MF is formed in the via holes VH6 and on the interlayer insulating film IL6 as illustrated in FIG. 11. The metal film MF has a thickness of, for example, 1.6 μm. That is, the metal film MF, which has a thickness larger than the height of each of the via hole VH6, is formed here.

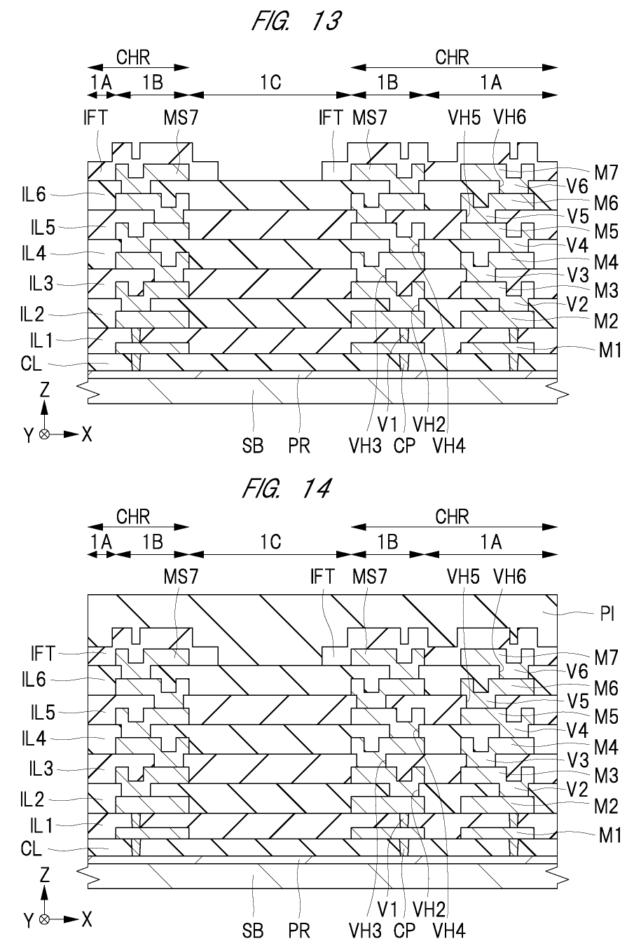

Next, the metal film MF is patterned by photolithography and etching as illustrated in FIG. 12. Thereby, the vias V6 made of the metal film MF in the via holes VH6, and the wirings MS7 and M7 made of the metal film MF on the interlayer insulating film IL6 are formed. The wiring MS7 formed in the seal ring region 1B and the wirings M7 formed in the circuit region 1A are made of the same metal film MF by the manufacturing steps, and are positioned at the same height. The wirings M1 to M6, the wiring MS7, the vias V1 to V6, and the contact plug CP, which are formed in the seal ring region 1B, configure the multilayer wiring. The wirings M1 to M7, the vias V1 to V6, and the contact plugs CP, which are formed in the circuit region 1A, configure the multilayer wiring. The concave portion (concave portion RC1 in FIG. 4) is formed on the upper surface of the wiring MS7 immediately on the via V6.

Next, the insulating film IFT made of, for example, silicon nitride is formed on the interlayer insulating film IL6, the wiring MS7, and the wirings M7 as illustrated in FIG. 13. Next, the insulating film IFT is patterned by photolithography and dry etching, thereby removing the insulating film IFT in the scribe region 1C.

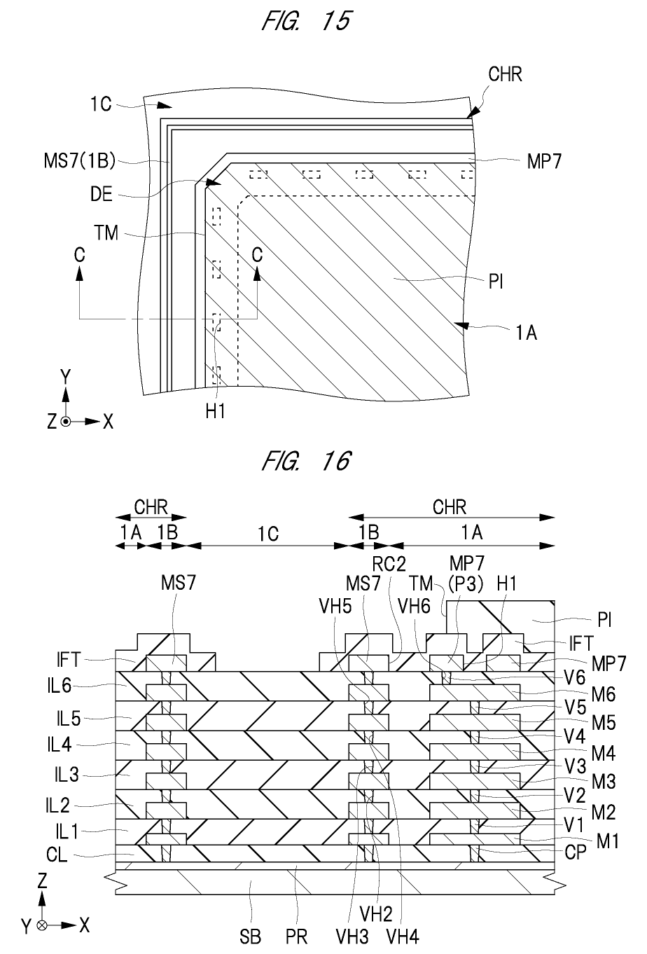

Next, the organic insulating film PI made of, for example, photosensitive polyimide is applied on the interlayer insulating film IL6 and the insulating film IFT as illustrated in FIG. 14. At this time, the upper surface of the viscous liquid organic insulating film PI is almost flat.

Next, as illustrated in FIG. 3, the organic insulating film PI is selectively exposed to light. That is, the organic insulating film PI is irradiated with ultraviolet light under use of a photomask by which a portion to be finally left in the organic insulating film PI is irradiated with light. Next, a portion having been not irradiated with the ultraviolet light in the organic insulating film PI is removed by the liquid developer. That is, a step of patterning the organic insulating film PI is performed. Thereby, a portion of the organic insulating film PI in the seal ring region 1B and the organic insulating film PI in the scribe region 1C are removed. The organic insulating film PI is patterned such that the organic insulating film PI terminates immediately on the wiring MS7 which is positioned closer to the edge portion of the chip region CHR than the concave portion on the upper surface of the wiring MS7.

The semiconductor substrate SB is thermally processed in the step of forming the organic insulating film PI. The semiconductor substrate SB including the organic insulating film PI is thermally processed also after the organic insulating film PI is developed. The organic insulating film PI is shrunk by the thermal processings.

The semiconductor device according to the first embodiment is completed through the above steps. Thereafter, the scribe region 1C including the semiconductor substate SB is cut by a dicer, thereby providing the plurality of semiconductor chips (semiconductor chips CH1 illustrated in FIGS. 7 and 8) made of the chip regions CHR. Next, the semiconductor chips are sealed by mold resin, thereby protecting the semiconductor chips.

### Effects of First Embodiment

Effects of the first embodiment will be described below.

As described in the chapter “DETAILS OF ROOM FOR IMPROVEMENT”, the semiconductor device in which the wiring, the interlayer insulating film and the like are protected by the organic insulating film has the room for improvement in preventing the peeling off of the end portion of the organic insulating film.

Accordingly, in the first embodiment, the organic insulating film PI terminates immediately on the wiring MS7 configuring the seal ring as illustrated in FIG. 4. Thereby, the thickness of the end portion of the organic insulating film PI is smaller than the thickness of the organic insulating film PI immediately on the concave portion RC2. One of reasons why the end portion of the organic insulating film PI peels off is that the thick portion of the organic insulating film PI remarkably shrinks when the organic insulating film PI is heated. In the first embodiment, the organic insulating film PI is terminated immediately on the wiring MS7 in order to make the thickness of the end portion of the organic insulating film PI uniformly small on the outer periphery of the organic insulating film PI. Thereby, the peeling off of the organic insulating film PI due to the large thickness of the organic insulating film PI can be prevented.

Further, since the organic insulating film PI terminates immediately on the wiring MS7, the peeling off of the organic insulating film PI due to the stayed liquid developer used in the step of patterning the organic insulating film PI can be prevented. That is, the end portion TM of the organic insulating film PI separates from the concave portion RC1 and the concave portion RC2 which are the portions having the higher possibility of the stayed liquid developer than that of the portion on the upper surface of the wiring MS7. Thus, the peeling off of the organic insulating film PI due to the contact between the liquid developer and the end portion of the organic insulating film PI can be prevented.

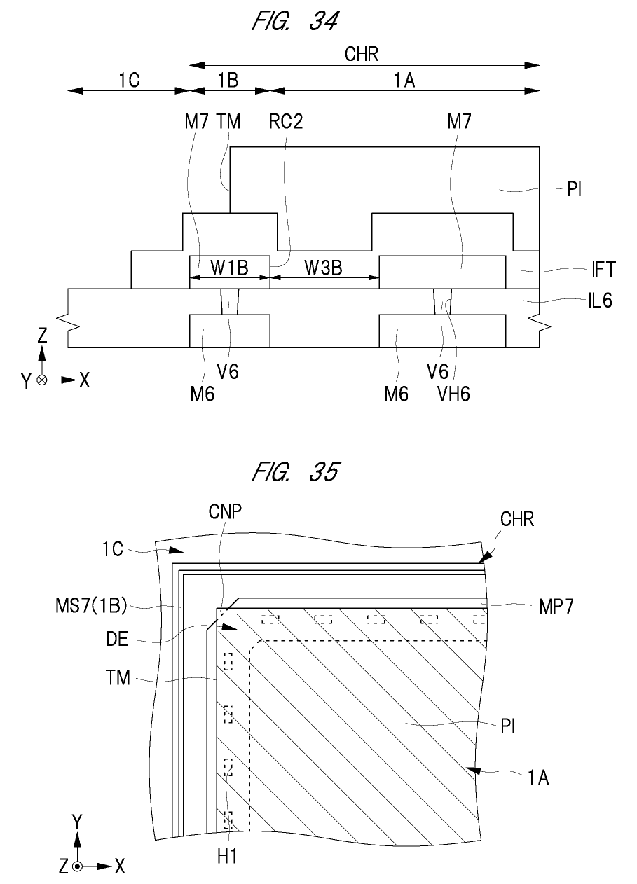

As illustrated in FIG. 6, the depth T1 of the concave portion RC1, which is positioned closer to the end portion TM of the organic insulating film PI than the concave portion RC2, is smaller than the depth T2 of the concave portion RC2. That is, the liquid developer is more difficult to stay in the concave portion RC1 than in the concave portion RC2. Thereby, even if the formation position of the end portion TM of the organic insulating film PI is different from the overlap position with the concave portion RC1 in plan view, the peeling off of the organic insulating film PI due to the contact between the liquid developer and the end portion of the organic insulating film PI can be prevented. A reason for this will be described below with reference to FIG. 34.

FIG. 34 is a cross-sectional view illustrating a semiconductor device according to a third comparative example. In FIG. 34, hatching is omitted. In the semiconductor device according to the third comparative example illustrated in FIG. 34, the organic insulating film PI is designed to terminate immediately on the wiring M7 configuring the seal ring. However, if the position of the end portion TM of the organic insulating film PI is made different by, for example, the accuracy of light exposure, the organic insulating film PI possibly terminates in the concave portion RC2 adjacent to the wiring M7 configuring the seal ring as illustrated in FIG. 33. Since the liquid developer is easier to stay in the concave portion RC2 than in the concave portion RC1, if the organic insulating film PI terminates in the concave portion RC2, the organic insulating film PI is in contact with the liquid developer and easily peels off. Thus, in the first embodiment, even if the organic insulating film PI terminates in the concave portion RC1 due to the positional difference of the organic insulating film PI, the peeling off due to the contact between the liquid developer and the end portion of the organic insulating film PI can be prevented.

Since the organic insulating film PI terminates immediately on the wiring MS7, the organic insulating film PI is not in contact with the dicer when the scribe region 1C is cut in the dicing step. Thus, foreign materials due to the contact between the organic insulating film PI and the dicer can be prevented.

In the short-wise direction of the wiring MS7, the organic insulating film PI terminates immediately on the wider wiring MS7 (first portion P1) of the wiring MS7 adjacent to the concave portion RC1. Thereby, in the short-wise direction of the wiring MS7, the influence of the positional difference of the end portion TM of the organic insulating film PI can be further prevented than the case in which the organic insulating film PI terminates immediately on the narrower wiring MS7 (second portion P2) of the wiring MS7 adjacent to the concave portion RC1. For example, if the position of the end portion TM of the organic insulating film PI is made different by the accuracy of exposure, the organic insulating film PI possibly terminates at a position separate from the wiring MS7. In this case, the end portion of the organic insulating film PI is thicker than that in the case in which the end portion of the organic insulating film PI is formed immediately on the wiring MS7. Consequently, the end portion of the organic insulating film PI remarkably shrinks when being heated, and easily peels off from the insulating film IFT. The first embodiment can prevent the influence of the positional difference of the end portion TM of the organic insulating film PI.

The manufacturing of the semiconductor device according to the first comparative example described with reference to FIG. 28 needs the step of forming the metal film in the via holes VH6 and on the interlayer insulating film IL6, and then, removing the metal film on the interlayer insulating film IL6. To the contrary, in the first comparative example, the vias and the wirings on the vias are made of the same metal film from one another, and thus, the step of removing the metal film can be omitted as different from the first comparative example.

### SECOND EMBODIMENT

### Configuration of Semiconductor Device

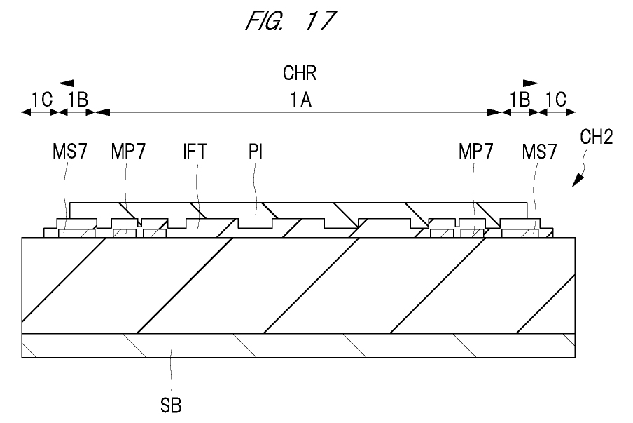

A configuration of a semiconductor device according to a second embodiment will be described below with reference to FIGS. 15 and 16. FIG. 15 is a plan view illustrating the semiconductor device according to the second embodiment. FIG. 16 is a cross-sectional view illustrating the semiconductor device taken along the line C-C of FIG. 15.

FIG. 15 illustrates a vicinity of a corner of the chip region CHR of the semiconductor device according to the second embodiment. In FIG. 15, the contour of the wiring covered with the organic insulating film PI is illustrated with a dashed line. As illustrated in FIG. 15, the semiconductor device configures the semiconductor wafer provided before the scribe region 1C is cut. As similar to the first embodiment, each of the chip regions CHR arranged in the matrix pattern on the upper surface of the semiconductor wafer is rectangular in plan view. The semiconductor wafer includes the scribe region 1C between the adjacent chip regions. The chip region CHR includes the circuit region 1A and the seal ring region 1B surrounding the circuit region 1A in plan view.

The semiconductor device according to the second embodiment is different from the semiconductor device according to the first embodiment in that the width of the wiring MS7 (that is the short-wise length of the wiring MS7) configuring the seal ring is smaller than the width of the wiring MP7 (that is the short-wise length of the wiring MP7). The semiconductor device according to the second embodiment is different from the semiconductor device according to the first embodiment in that the wiring MP7 includes a plurality of holes H1. The wiring MP7 corresponds to the wiring M7 illustrated in FIGS. 3 and 5. The wiring MP7 is continuously formed along the outer periphery of the circuit region 1A in plan view. The wiring MP7 is a wiring formed adjacent to the wiring MS7 and the seal ring region 1B. In the first embodiment, the end portion TM of the organic insulating film PI is positioned on the wiring MS7 (more specifically, a portion of the wiring MS7 which does not overlap the concave portion RC1) provided in the seal ring region 1B. To the contrary, the second embodiment is different from the first embodiment since the end portion TM of the organic insulating film PI is positioned on the wiring MP7 (more specifically, a portion of the wiring MP7 which does not overlap the holes H1) provided in the circuit region 1A.

As illustrated in FIG. 16, as similar to the first embodiment, the semiconductor device according to the second embodiment includes the semiconductor substrate SB including the semiconductor region PR, the interlayer insulating film CL, and the interlayer insulating films IL1 to IL6. In the semiconductor device according to the second embodiment, the contact plugs CP, the wirings M1, the vias V1, and the wirings M2 are provided in the seal ring region 1B and the circuit region 1A. The vias V1 penetrating the interlayer insulating film IL1 are formed on the wirings M1. The interlayer insulating film IL1, the wirings M1, and the vias V1 configure the first wiring layer.

The second wiring layer is formed on the first wiring layer. The second wiring layer includes the wirings M2, the interlayer insulating film IL2, and the vias V2. The wirings M2 are formed on the interlayer insulating film IL1 and the vias V1, and are connected to the vias V1. The interlayer insulating film IL2 is formed on the interlayer insulating film IL1 and covers the wirings M2. The vias V2 are embedded in the via holes VH2 penetrating the interlayer insulating film IL2 on the wirings M2, and are connected to the wirings M2. The third wiring layer, the fourth wiring layer, the fifth wiring layer, and the sixth wiring layer, which have the same configuration as that of the second wiring layer, are sequentially formed on the second wiring layer.

The wiring MS7 is formed on the interlayer insulating film IL6 and the via V6 in the seal ring region 1B. The wiring MS7 is connected to the via V6. The contact plug CP, the vias V1 to V6, the wirings M1 to M6, and the wiring MS7, which are formed in the seal ring region 1B, configure the multilayer wiring. The wiring MS7 configures the uppermost wiring of the multilayer wiring.

The wiring MP7 is formed on the interlayer insulating film IL6 and the via V6 at the edge portion of the circuit region 1A in plan view. The wiring MP7 is connected to the via V6. The contact plug CP, the vias V1 to V6, the wirings M1 to M6, and the wiring MP7, which are formed in the circuit region 1A, configure the multilayer wiring. The wiring MP7 configures the uppermost wiring of the multilayer wiring. Although not illustrated, a wiring is formed on the interlayer insulating film IL6 in the circuit region 1A surrounded by the wiring MP7 in plan view. This wiring is a wiring in the same layer as those of the wiring MS7 and the wiring MP7, and configures the uppermost wiring of the multilayer wiring.

The wiring MP7 includes the holes H1 penetrating the wiring layer MP7 in the Z direction. The side surface of the hole H1 is the side surface of the wiring MP7, and the bottom surface of the hole H1 is the upper surface of the interlayer insulating film IL6. Each of the interlayer insulating films IL1 to IL6 is mainly made of, for example, a silicon oxide film. Each of the wirings M1 to M6, MS7, and MP7 is mainly made of, for example, aluminum (Al). Each of the vias V1 to V6 is the conductive connector and is mainly made of, for example, tungsten (W).

The insulating film IFT is formed on the wiring MS7, the wiring MP7, and the interlayer insulating film IL6. The insulating film IFT is, for example, a silicon nitride film. The upper surfaces and the side surfaces of the wirings MS7 and MP7 are covered with the insulating film IFT. The upper surface of the insulating film IFT has surface irregularity to follow the underlying shape of the insulating film IFT, that is, the shapes of the upper surfaces and the side surfaces of the wirings MP7 and MS7 and the upper surface of the interlayer insulating film IL6. The insulating film IFT is formed only on both edge portions of the scribe region 1C in the short-wise direction.

The organic insulating film PI is formed on the insulating film IFT. The organic insulating film PI is made of, for example, polyimide. The organic insulating film PI partially covers the wiring MP7 in the circuit region 1A and entirely covers the wiring MS7 in the seal ring region 1B. That is, the organic insulating film PI and the wiring MS7 separate from each other. Although not illustrated, the organic insulating film PI and the insulating film IFT include openings for exposing the upper surfaces of the wirings MP7. The upper surfaces of the wirings MP7 exposed at the bottoms of the openings configure, for example, electrode pads connected to boding wires.

And, for example, a semiconductor element is formed at the center of the circuit region 1A in plan view although not illustrated. The semiconductor element is, for example, a metal oxide semiconductor field effect transistor (MOSFET). The MOSFET includes the upper surface of the semiconductor region PR, that is, the upper surface of the semiconductor substrate SB as a channel region.

The wirings M1 to M6, the wiring MS7, the vias V1 to V6, and the contact plug CP, which configure the multilayer wiring in the seal ring region 1B, are electrically connected to one another. The multilayer wiring formed in the seal ring layer 1B configures a seal ring. The seal ring is electrically connected to the semiconductor substrate SB via the semiconductor region PR. The wirings M1 to M6, the wiring MP7, the vias V1 to V6, and the contact plug CP, which configure the multilayer wiring in the circuit region 1A, are electrically connected to one another. The multilayer wiring formed in the circuit region 1A is electrically connected to the semiconductor substrate SB via the semiconductor region PR. The multilayer wiring formed in the circuit region 1A is electrically connected to the MOSFET and configures a circuit. That is, the wiring MP7 is a wiring electrically connected to the circuit. To the contrary, the seal ring does not configure a circuit.

The wiring MP7 plays a role of supplying a VDD voltage or a ground voltage to the element. Thus, the short-wise width of the wiring MP7 is larger than the short-wise width of each of the other wirings in the same layer as that of the wiring MP7. As described with reference to FIG. 32, the insulating film IFT possibly cracks when the relatively wide wiring MP7 shrinks at high temperature. Thus, the wiring MP7 on the outer periphery of the chip region CHR includes the plurality of holes H1. The holes H1 are arranged to separate from one another in the extending direction of the wiring MP7 in plan view. The holes H1 may be arranged in a staggered pattern as illustrated in FIG. 32.

The wiring MP7 includes a third portion P3 being positioned closer to the edge portion of the chip region CHR than the hole H1. The third portion P3 of the wiring MP7 is positioned closer to the edge portion of the chip region CHR than the arrangement region of the holes H1 arranged in the extending direction of the wiring MP7.

The concave portion RC2 is present between the adjacent wirings MS7 and MP7. The concave portion RC2 is almost as deep as the hole H1.

The organic insulating film PI is continuously formed from the center of the circuit region 1A to the portion of the wiring MP7. In other words, the end portion TM of the organic insulating film PI is positioned at the portion of the wiring MP7 in the circuit region 1A, the portion being closest to the seal ring region 1B. The concave portion RC1 and the holes H1 are covered with the organic insulating film PI. That is, in the short-wise direction (the X direction in FIG. 16) of the wiring MP7, the organic insulating film PI terminates on the portion of the wiring MP7 being adjacent to the hole H1 as well as being positioned closer to the edge portion (periphery) of the chip region CHR.

As illustrated in FIG. 15, the end portion TM of the organic insulating film PI is positioned between the hole H1 and the edge portion of the wiring MP7 being positioned closer to the edge portion of the chip region CHR, and extends along the edge portion of the wiring MP7 being positioned closer to the edge portion of the chip region CHR in plan view. That is, the end portion TM of the organic insulating film PI is positioned immediately on the third portion P3. In other words, the end portion TM of the organic insulating film PI overlaps the third portion P3 in plan view. The end portion TM of the organic insulating film PI is positioned away from the edge portion of the wiring MP7 and the hole H1 in plan view.

The wiring MP7 includes a portion which extends in the X direction along one edge portion of the chip region CHR, and a portion which extends in the Y direction along the other edge portion of the chip region CHR. The wiring MP7 extending in the X direction is connected to the wiring MP7 extending in the Y direction by the wiring MP7 extending in a direction obliquely crossing both the X direction and the Y direction in plan view. That is, the wiring MP7 in vicinity of a corner of the chip region CHR includes a portion DE extending in the direction obliquely crossing both the X direction and the Y direction. The portion DE extends in a direction of, for example, 45 degrees from the X direction and the Y direction in plan view. The end portion TM of the organic insulating film PI on the portion DE extends on the portion DE along the extending direction of the portion DE. That is, the organic insulating film PI terminates along the edge portion (periphery) of the wiring MP7 on each of the portion of the wiring MP7 extending in the X direction, the portion thereof extending in the Y direction, and the portion DE thereof in plan view.

A semiconductor chip, which is obtained from the semiconductor wafer by cutting the scribe region 1C, is configured as illustrated in FIG. 17. FIG. 17 is a schematic cross-sectional view illustrating a semiconductor chip CH2 obtained by cutting the scribe region 1C. FIG. 17 schematically illustrates a configuration of the semiconductor chip CH2, and particularly simply illustrates a configuration of the multilayer wiring and a configuration of the circuit region 1A. As illustrated in FIG. 17, the organic insulating film PI is formed from the center of the circuit region 1A to the edge portion of the circuit region 1A in plan view. In other words, the organic insulating film PI is formed from the portion of the wiring MP7 close to one edge portion of the semiconductor chip CH2 to the portion of the wiring MP7 close to the other edge portion thereof.

### Method of Manufacturing Semiconductor Device

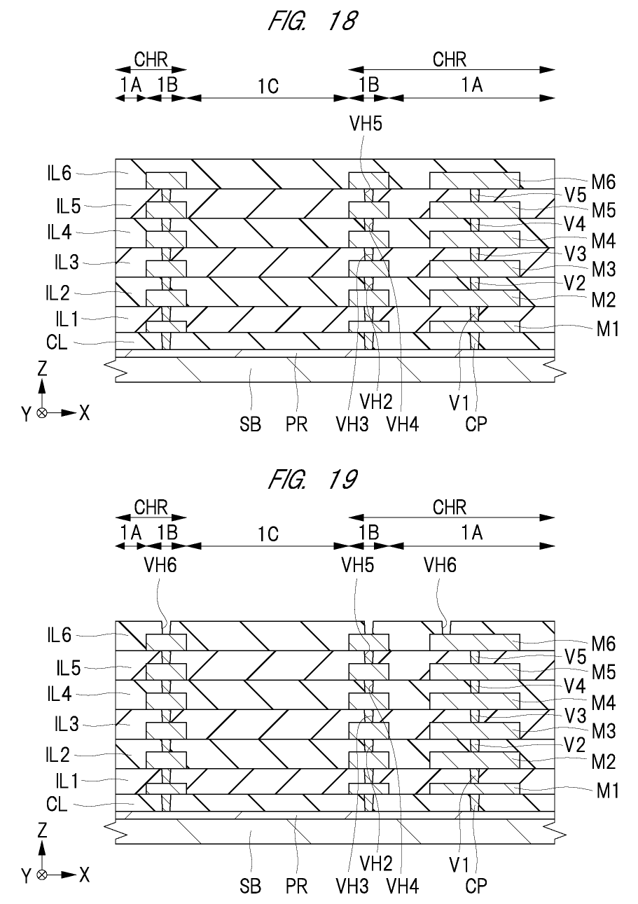

A method of manufacturing the semiconductor device according to the second embodiment will be described below with reference to FIGS. 16 to 23. FIGS. 18 to 23 are cross-sectional views illustrating the steps of manufacturing the semiconductor device according to the second embodiment.

First, as illustrated in FIG. 18, the p-type semiconductor substrate SB is prepared. Next, p-type impurities are implanted into the upper surface of the semiconductor substrate SB by ion implantation. Thereby, the semiconductor region PR is formed. Next, the interlayer insulating film CL and the contact plugs CP as conductive connectors penetrating the interlayer insulating film CL are formed on the semiconductor substrate SB in the seal ring region 1B and the circuit region 1A. Next, the first wiring layer, which includes the wirings M1, the interlayer insulating film IL1, and the vias V1 penetrating the interlayer insulating film IL1 on the wirings M1, is formed on the interlayer insulating film CL and the contact plugs CP.

Next, the second wiring layer, the third wiring layer, the fourth wiring layer, and the fifth wiring layer are formed on the first wiring layer by the same steps as the steps of forming the first wiring layer. The second wiring layer includes the wirings M2, the interlayer insulating film IL2, and the vias V2 penetrating the interlayer insulating film IL2 on the wirings M2. The third wiring layer includes the wirings M3, the interlayer insulating film IL3, and the vias V3 penetrating the interlayer insulating film IL3 on the wirings M3. The fourth wiring layer includes the wirings M4, the interlayer insulating film IL4, and the vias V4 penetrating the interlayer insulating film IL4 on the wirings M4. The fifth wiring layer includes the wirings M5, the interlayer insulating film IL5, and the vias V5 penetrating the interlayer insulating film IL5 on the wirings M5. The wirings M6 and the interlayer insulating film IL6 are formed on the interlayer insulating film IL5 by the same steps as the steps of forming the wirings M1 and the interlayer insulating film IL1.

Next, the via holes VH6, which penetrate the interlayer insulating film IL6 and expose the upper surfaces of the wirings M6, are formed by photolithography and dry etching as illustrated in FIG. 19. The height of the via hole VH6 is, for example, 1.1 μm.

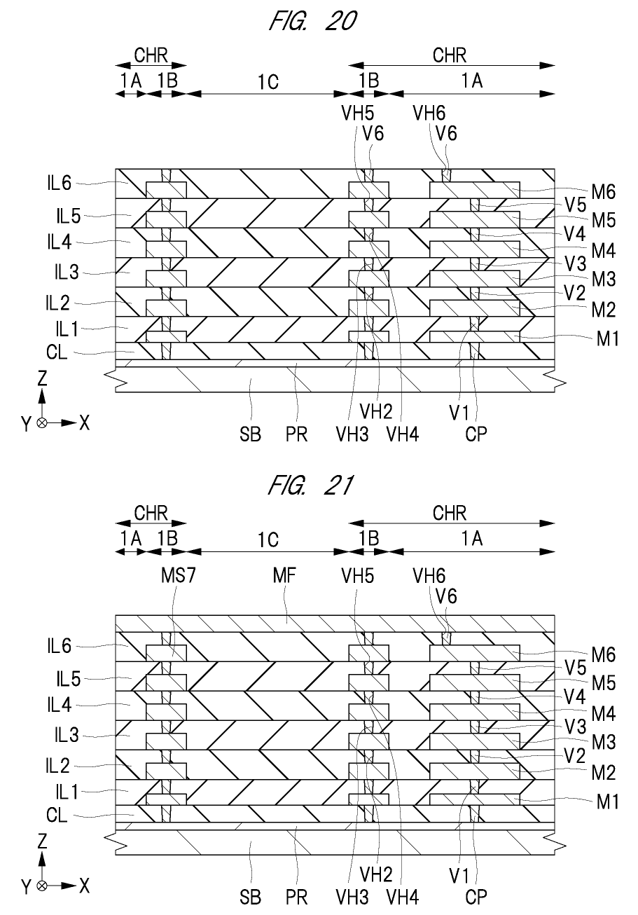

Next, a metal film is formed in the via holes VH6 and on the interlayer insulating film IL6 as illustrated in FIG. 20. Next, the metal film on the interlayer insulating film IL6 is removed. Thereby, the vias V6, which are made of the metal film remaining in the via holes VH6, are formed.

Next, the metal film MF is formed on the interlayer insulating film IL6 and the vias V6 penetrating the interlayer insulating film IL6 as illustrated in FIG. 21.

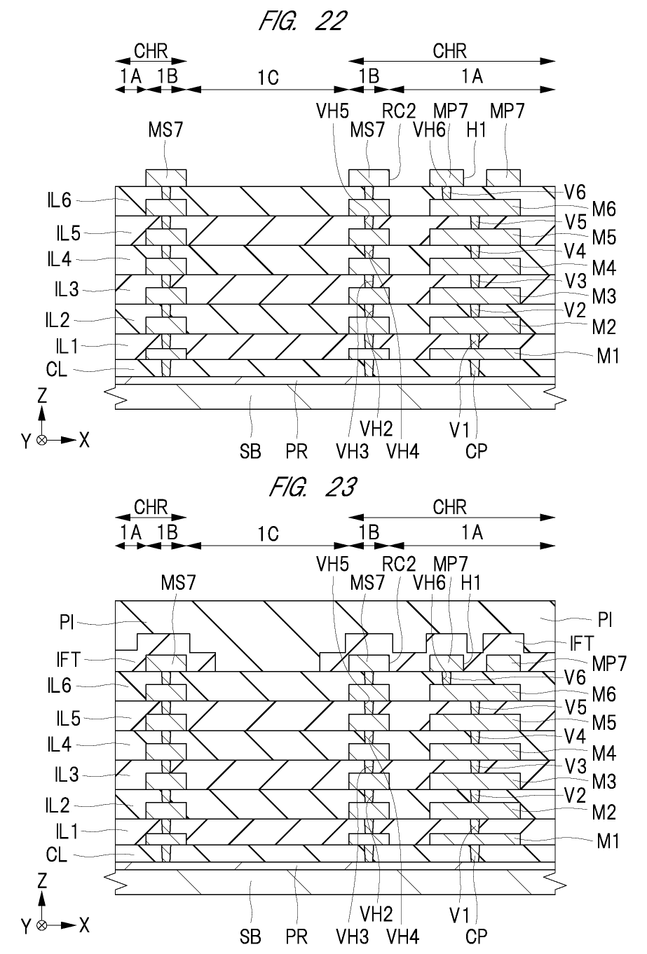

Next, the metal film MF on the interlayer insulating film IL6 is patterned, thereby forming the wiring MS7 in the seal ring region 1B and the wiring MP7 in the circuit region 1A as illustrated in FIG. 22. The center of the wiring MP7 in the short-wise direction includes the hole H1 as through-hole. The interlayer insulating film IL6 is exposed at the bottom of the hole H1.

Next, the insulating film IFT made of, for example, silicon nitride is formed on the interlayer insulating film IL6, the wiring MS7, and the wiring MP7 as illustrated in FIG. 23. Next, the insulating film IFT is patterned by photolithography and dry etching, thereby removing the insulating film IFT in the scribe region 1C. Next, the organic insulating film PI made of, for example, photosensitive polyimide is applied on the interlayer insulating film IL6 and the insulating film IFT.

As illustrated in FIG. 16, the organic insulating film PI is selectively exposed to light. That is, the organic insulating film PI is irradiated with ultraviolet light under use of a photomask by which a portion to be finally left in the organic insulating film PI is irradiated with light. Next, a portion having been not irradiated with the ultraviolet light in the organic insulating film PI is removed by the liquid developer. That is, a step of patterning the organic insulating film PI is performed. Thereby, a portion of the organic insulating films PI in the seal ring region 1B and the organic insulating films PI in the scribe region 1C are removed. The organic insulating film PI is patterned such that the organic insulating film PI terminates immediately on the wiring MP7 being positioned closer to the edge portion of the chip region CHR than the hole H1.

The semiconductor substrate SB is thermally processed in the step of forming the organic insulating film PI. The semiconductor substrate SB including the organic insulating film PI is thermally processed also after the organic insulating film PI is developed. The organic insulating film PI is shrunk by the thermal processings.

The semiconductor device according to the second embodiment is completed through the above steps. Thereafter, the scribe region 1C including the semiconductor substate SB is cut by a dicer, thereby providing the plurality of semiconductor chips made of the chip regions CHR. Next, the semiconductor chips are sealed by mold resin, thereby protecting the semiconductor chips.

### Effects of Second Embodiment

Effects of the second embodiment will be described below.

As described in the chapter “DETAILS OF ROOM FOR IMPROVEMENT”, the semiconductor device in which the wiring, the interlayer insulating film and the like are protected by the organic insulating film has the room for improvement in preventing the peeling off of the end portion of the organic insulating film.

Accordingly, in the second embodiment, the organic insulating film PI terminates on the portion of the wiring MP7 provided in the circuit region 1A, the portion not overlapping the hole H1 as illustrated in FIG. 16. Thereby, the thickness of the end portion of the organic insulating film PI is smaller than the thickness of the organic insulating film PI immediately on the hole H1 in the wiring MP7 and the thickness of the organic insulating film PI immediately on the concave portion between the wiring MP7 and its adjacent wiring in the X direction. In this case, the organic insulating film PI terminates immediately on the wiring MP7, that is, on the portion not overlapping the hole H1 in the wiring MP7 such that the end portion of the organic insulating film PI on the outer periphery of the organic insulating film PI is uniformly thin. The end portion TM of the organic insulating film PI does not overlap the hole H2 (the hole H1 in the second embodiment) in plan view as different from the second comparative example illustrated in FIG. 32. Thereby, the peeling off of the organic insulating film PI due to the large thickness of the organic insulating film PI can be prevented.

Since the end portion TM of the organic insulating film PI does not overlap the hole H1 in plan view, the peeling off of the organic insulating film PI due to the stayed liquid developer used in the step of patterning the organic insulating film PI can be prevented. The hole H1 is the portion with the higher possibility of the staying of the liquid developer than that of the upper surface of the wiring MP7. Thus, the organic insulating film PI terminates at the position separate from the hole H1, thereby preventing the peeling off of the organic insulating film PI due to the contact between the liquid developer and the end portion of the organic insulating film PI.

Since the organic insulating film PI terminates immediately on the wiring MS7, the organic insulating film PI is not in contact with the dicer when the scribe region 1C is cut in the dicing step. Thus, foreign materials due to the contact between the organic insulating film PI and the dicer can be prevented.

The organic insulating film PI terminates immediately on the wiring MP7 with the larger width (length in the X direction in FIG. 16) than the wiring MS7. Thereby, even if the formation position of the end portion TM of the organic insulating film PI is shifted, the termination of the organic insulating film PI at the separate position from the wiring MS7 can be prevented.

FIG. 35 is a plan view illustrating a semiconductor device according to a fourth comparative example. The planar layout of the fourth comparative example is similar to the planar layout of the second embodiment illustrated in FIG. 15 except for the layout of the end portion TM of the organic insulating film PI. In the fourth comparative example, the wiring MP7 includes a portion DE which extends obliquely to each of the X direction and the Y direction that are the extending directions of the edge portion of the chip region CHR as illustrated in FIG. 35. A corner CNP of the organic insulating film PI is positioned closer to the outside than the edge portion of the portion DE being positioned closer to the edge portion of the chip region CHR in plan view. In this case, the corner CNP of the organic insulating film PI is thicker than the organic insulating film PI immediately on the wiring MP7. Thus, the corner CNP of the organic insulating film PI is easily deformed by the shrinkage on heating, and therefore, easily peels off from the insulating film IFT.

To the contrary, in the second embodiment, the end portion TM of the organic insulating film PI on the portion DE extends immediately on the portion DE along the extending direction of the portion DE. Thereby, the peeling off of the organic insulating film PI in vicinity of the portion DE due to the large thickness of the organic insulating film PI can be prevented.

In the foregoing, the invention made by the inventors of the present application has been concretely described based on the embodiments. However, it is needless to say that the present invention is not limited to the foregoing embodiments, and various modifications and alterations can be made within the scope of the present invention.

For example, in the first and second embodiments, the semiconductor device provided before the scribe region is cut in the dicing step has been described. To the contrary, the first and second embodiments may be applied to a semiconductor device provided after the scribe region is cut, that is, the semiconductor chip.

For example, as described in the first embodiment, the wirings M1 to M6 and MS7, which configure the multilayer wiring in the seal ring region 1B, are the virtual wirings. The multilayer wiring formed in the seal ring region 1B may be also electrically connected to, for example, the coil (particularly the portion to which the ground voltage is supplied) made of the lower inductor.

For example, in the first and second embodiments, the example in which the semiconductor region PR is formed on the upper surface of the semiconductor substrate SB has been described. However, a semiconductor substrate SB without the semiconductor region PR may also applied.

What is claimed is:

1. A semiconductor device comprising:
a semiconductor substrate including a chip region having a circuit region and a seal ring region positioned around the circuit region in plan view;
a first interlayer insulating film formed on the semiconductor substrate;
a first wiring formed on the first interlayer insulating film in the circuit region;
a second wiring formed on the first interlayer insulating film in the seal ring region;
an inorganic insulating film formed on the first interlayer insulating film so as to cover the first wiring and the second wiring; and
an organic insulating film formed on the inorganic insulating film,
wherein the seal ring region is arranged along an edge portion of the chip region,
wherein a concave portion is formed on an upper surface of the second wiring,
wherein the organic insulating film is formed from the circuit region to the seal ring region, and
wherein the organic insulating film is formed such that an end portion of the organic insulating film is positioned on a first portion of the second wiring, the first portion being positioned closer to the edge portion of the chip region than the concave portion.

2. The semiconductor device according to claim 1,
wherein the second wiring extends along an extending direction of the seal ring region, and
wherein a width of the first portion of the second wiring, the first portion being positioned closer to the edge portion of the chip region than the concave portion, is larger than a width of a second portion of the second wiring, the second portion being farther from the edge portion of the chip region than the concave portion.

3. The semiconductor device according to claim 1,
wherein a depth of the concave portion is smaller than a thickness of each of the first wiring and the second wiring.

4. The semiconductor device according to claim 1, further comprising:
a second interlayer insulating film formed on the semiconductor substrate;
a third wiring formed on the second interlayer insulating film in the circuit region; and
a fourth wiring formed on the second interlayer insulating film in the seal ring region,
wherein the first interlayer insulating film is formed on the second interlayer insulating film such that portion of the third wiring and a portion of the fourth wiring are exposed,
wherein the portion of the third wiring is exposed in a first via hole formed in the first interlayer insulating film,
wherein the portion of the fourth wiring is exposed in a second via hole formed in the first interlayer insulating film,
wherein the first wiring is connected to the third wiring positioned in the first via hole,
wherein the second wiring is connected to the fourth wiring positioned in the second via hole, and
wherein the concave portion is positioned on the second via hole.

5. The semiconductor device according to claim 1,
wherein an upper surface of the inorganic insulating film has surface irregularity to follow shapes of upper surfaces and side surfaces of the first wiring and the second wiring and an upper surface of the first interlayer insulating film.

6. The semiconductor device according to claim 1,
wherein the second wiring does not configure a circuit.

7. The semiconductor device according to claim 1,
wherein the organic insulating film is made of polyimide.

8. A semiconductor device comprising:
a semiconductor substrate including a chip region having a circuit region and a seal ring region positioned around the circuit region in plan view;
a first interlayer insulating film formed on the semiconductor substrate,
a first wiring formed on the first interlayer insulating film in the circuit region;
a second wiring formed on the first interlayer insulating film in the seal ring region;
an inorganic insulating film formed on the first interlayer insulating film to cover the first wiring and the second wiring; and
an organic insulating film formed on the inorganic insulating film,
wherein the seal ring region is arranged along an edge portion of the chip region,
wherein the first wiring includes a hole penetrating the first wiring in a height direction, and
wherein the organic insulating film is formed such that an end portion of the organic insulating film is positioned on a first portion of the first wiring, the first portion being positioned closer to the edge portion of the chip region than the hole.

9. The semiconductor device according to claim 8,
wherein the first wiring extends along an edge portion of the circuit region, and
wherein a plurality of the holes are formed along an extending direction of the first wiring.

10. The semiconductor device according to claim 8,
wherein in plan view, the first wiring includes:
a second portion extending in a first direction;
a third portion extending in a second direction perpendicular to the first direction; and
a fourth portion obliquely crossing the first direction and the second direction, and
wherein in plan view, the organic insulating film terminates immediately on each of the second portion, the third portion, and the fourth portion to be along an edge portion of the first wiring.

11. The semiconductor device according to claim 8,
wherein an upper surface of the inorganic insulating film has surface irregularity to follow shapes of upper surfaces and side surfaces of the first wiring and the second wiring and an upper surface of the first interlayer insulating film.

12. The semiconductor device according to claim 8,
wherein the first wiring configures a circuit.

13. The semiconductor device according to claim 8,
wherein the organic insulating film is made of polyimide.
